(19) United States
(12) Patent Application Publication
(10) Pub. No.: US 2025/0376548 A1
(43) Pub. Date: Dec. 11, 2025

(54) PHOTOSENSITIVE RESIN COMPOSITION, PHOTOSENSITIVE RESIN FILM MANUFACTURED USING THE COMPOSITION, AND COLOR FILTER

(71) Applicant: SAMSUNG SDI CO., LTD., Yongin-si (KR)

(72) Inventors: Kwangwon Seo, Suwon-si (KR); Chang-Hyun Kwon, Suwon-si (KR); Heejo Moon, Suwon-si (KR); Ickjin Kim, Suwon-si (KR); Subin Park, Suwon-si (KR); Youngmin Jeon, Suwon-si (KR); Baek Soung Park, Suwon-si (KR)

(21) Appl. No.: 19/229,171

(22) Filed: Jun. 5, 2025

(30) Foreign Application Priority Data
Jun. 7, 2024 (KR) 10-2024-0074305

(51) Int. Cl. C08F 2/50; C07F 3/06; G02B 1/04; G02B 5/20; G03F 7/038

(52) U.S. Cl. CPC C08F 2/50; C07F 3/06; G02B 1/04; G02B 5/206; G03F 7/0382

(57) ABSTRACT

A photosensitive resin composition, a photosensitive resin film manufactured using the composition, and a color filter, a photosensitive resin composition, including a colorant; a photopolymerizable compound; a photopolymerization initiator; a binder resin; and a solvent, wherein the colorant includes a pigment, a dispersant, a dispersion binder, and a dispersion aid represented by Chemical Formula 1,

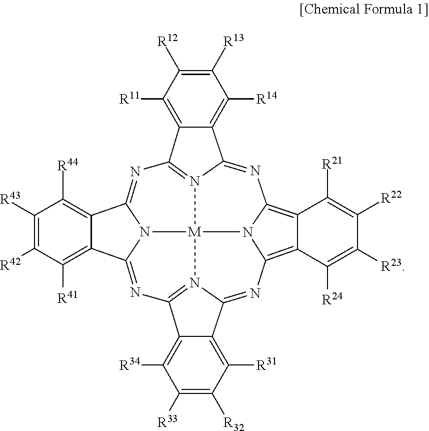

### CROSS-REFERENCE TO RELATED APPLICATION

This application claims priority to and the benefit of Korean Patent Application No. 10-2024-0074305 filed with the Korean Intellectual Property Office on Jun. 7, 2024, the entire contents of which are incorporated herein by reference.

### BACKGROUND

### 1. Field

Embodiments relate to a photosensitive resin composition, a photosensitive resin film manufactured using the same, and a color filter.

### 2. Description of the Related Art

A liquid crystal display device is a type of display that has an advantage of lightness, thinness, low cost, low power consumption for operation, and improved adherence to an integrated circuit and has been more widely used for a laptop computer, a monitor, and a TV screen.

The liquid crystal display device may include a lower substrate on which a black matrix, a color filter, and an ITO pixel electrode are formed, and an upper substrate on which an active circuit portion including a liquid crystal layer, a thin film transistor, and a capacitor layer and an ITO pixel electrode are formed.

Color filters may be formed in a pixel region by sequentially stacking a plurality of color filters (e.g., formed of three primary colors such as red (R), green (G), and blue (B) in a predetermined order to form each pixel, and a black matrix layer may be disposed in a predetermined pattern on a transparent substrate to form a boundary between the pixels.

The pigment dispersion method that is one of methods of forming a color filter provides a colored thin film by repeating a series of processes such as coating a photopolymerizable composition including a colorant on a transparent substrate including a black matrix, exposing a formed pattern to light, removing a non-exposed part with a solvent, and thermally curing the same.

A coloring photosensitive resin composition used for manufacturing a color filter according to the pigment dispersion method may include an alkali soluble resin, a photopolymerization monomer, a photopolymerization initiator, an epoxy resin, a solvent, other additives, or the like.

The pigment dispersion method may be applied to manufacture an LCD such as a mobile phone, a laptop, a monitor, and TV.

### SUMMARY

The embodiments may be realized by providing a photosensitive resin composition, including a colorant; a photopolymerizable compound; a photopolymerization initiator; a binder resin; and a solvent, wherein the colorant includes a pigment, a dispersant, a dispersion binder, and a dispersion aid represented by Chemical Formula 1,

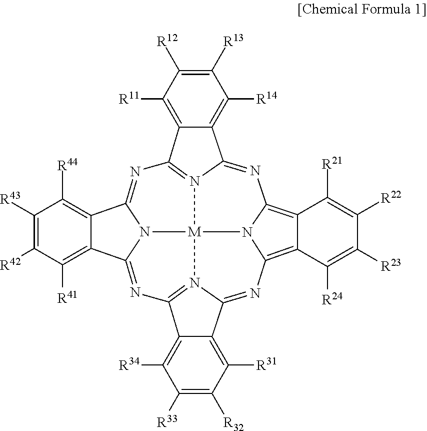

in Chemical Formula 1, M is Cu or Zn, R¹¹ to R¹⁴, R²¹ to R²⁴, and R³¹ to R³⁴ are each independently a hydrogen atom, a halogen atom, a hydroxy group, or a substituted or unsubstituted C1 to C20 alkyl group, and R⁴¹ to R⁴⁴ are each independently a hydrogen atom, a halogen atom, a hydroxy group, a substituted or unsubstituted C1 to C20 alkyl group, a substituted or unsubstituted C1 to C20 alkoxy group, or a substituted or unsubstituted C6 to C20 aryloxy group, provided that at least one of R⁴¹ to R⁴⁴ is a C1 to C20 alkoxy group or a C6 to C20 aryloxy group having a substituted or unsubstituted C1 to C20 oxyalkylene group as a linking group and an amine group as a substituent at the terminal end, or a C6 to C20 aryloxy group having an amine group as a substituent at the terminal end.

The embodiments may be realized by providing a photosensitive resin film manufactured using the photosensitive resin composition according to an embodiment.

The embodiments may be realized by providing a color filter including the photosensitive resin film according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout. As used herein, the term “or” is not necessarily an exclusive term, e.g., “A or B” would include A, B, or A and B.

As used herein, when specific definition is not otherwise provided, “substituted” refers to replacement of at least one hydrogen atom of a compound by a substituent of a halogen atom (F, Cl, Br, or I), a hydroxy group, C1 to C20 alkoxy group, a nitro group, a cyano group, amine group, imino group, an azido group, an amidino group, a hydrazino group, a hydrazono group, a carbonyl group, a carbamyl group, a thiol group, an ester group, ether group, a carboxyl group or a salt thereof, sulfonic acid group or a salt thereof, phosphoric acid or a salt thereof, C1 to C20 alkyl group, C2 to C20 alkenyl group, C2 to C20 alkynyl group, C6 to C30 aryl group, C3 to C20 cycloalkyl group, C3 to C20 cycloalkenyl group, C3 to C20 cycloalkynyl group, C2 to C20 heterocycloalkyl group, C2 to C20 heterocycloalkenyl group, C2 to C20 heterocycloalkynyl group, or a combination thereof.

As used herein, when specific definition is not otherwise provided, a “heterocycloalkyl group”, a “heterocycloalkenyl group”, a “heterocycloalkynyl group,” and a “heterocycloalkylene group” refer to each cyclic compound of cycloalkyl, cycloalkenyl, cycloalkynyl, and cycloalkylene including at least one heteroatom of N, O, S, or P.

As used herein, when specific definition is not otherwise provided, “(meth)acrylate” refers to both “acrylate” and “methacrylate”.

As used herein, when a definition is not otherwise provided, the term “combination” refers to mixing or copolymerization. In addition, “copolymerization” refers to block copolymerization to random copolymerization and “copolymer” refers to a block copolymer to a random copolymer.

As used herein, when a definition is not otherwise provided, in chemical formula, hydrogen is bonded at the position when a chemical bond is not drawn where supposed to be given.

As used herein, when specific definition is not otherwise provided, “*” indicates a point where the same or different atom or chemical formula is linked.

As used herein, when a definition is not otherwise provided, “particle diameter” may mean the diameter of a particle, and the particle diameter may be the Z-average value of the particle diameter measured through dynamic light scattering.

An image sensor is a semiconductor that converts photons into electrons and displays them on a display device or stores them in a storage device. A image sensor may be classified into a charge coupled device (CCD) image sensor or a complementary metal-oxide semiconductor (CMOS) image sensor according to a manufacturing process and an application method. Meanwhile, the image sensor may have a color filter including filter segments of additive mixed primary colors of red, green, and blue.

For a green color filter for an image sensor, the transmittance may be low, e.g., in the wavelength range of 380 nm to 480 nm and 630 nm to 700 nm, and the transmittance may be high, e.g., in the wavelength range of 480 nm to 630 nm to increase the sensor sensitivity. In an implementation in order to implement an ultra-thin film of less than or equal to 0.5 μm, the absorption intensity of the color material may be very excellent, so that a small amount of color material may exhibit low transmittance in the required region. In an embodiment, in order to implement a green color filter having excellent sensor sensitivity and capable of implementing a thin film, a dispersion aid that simultaneously introduces a tertiary amine polar group and an ether linking group structure to secure dispersion stability even if a high content of the dispersion aid is introduced into a phthalocyanine dye structure having a high absorption dye structure is used. The dispersion aid of the structure may be introduced in a high content into a green pigment dispersion, thereby helping produce a pigment dispersion with excellent coloring power. In an implementation, a photosensitive resin composition using this may be prepared, and the photosensitive resin composition may exhibit excellent coloring power compared to a photosensitive resin composition for a color filter using a different pigment dispersion even at an ultra-thin film thickness of, e.g., 0.5 μm or less, and also may exhibit characteristics such as heat resistance and chemical resistance that are equivalent to or higher than those of another pigment dispersion.

### (Photosensitive Resin Composition)

Some example embodiments may provide a photosensitive resin composition including, e.g., (A) a colorant; (B) a photopolymerizable compound; (C) a photopolymerization initiator; (D) a binder resin; and (E) a solvent. In an implementation, the colorant may include, e.g., a pigment, a dispersant, a dispersion binder, and a dispersion aid represented by Chemical Formula 1.

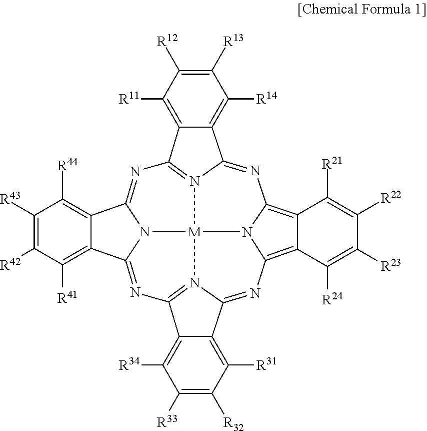

In Chemical Formula 1, M may be, e.g., Cu or Zn.

R¹¹ to R¹⁴, R²¹ to R²⁴, and R³¹ to R³⁴ may each independently be, e.g., a hydrogen atom, a halogen atom, a hydroxy group, or a substituted or unsubstituted C1 to C20 alkyl group.

R⁴¹ to R⁴⁴ may each independently be, e.g., a hydrogen atom, a halogen atom, a hydroxy group, a substituted or unsubstituted C1 to C20 alkyl group, a substituted or unsubstituted C1 to C20 alkoxy group, or a substituted or unsubstituted C6 to C20 aryloxy group.

In an implementation, at least one of R⁴¹ to R⁴⁴ may be, e.g., a C1 to C20 alkoxy group or a C6 to C20 aryloxy group having a substituted or unsubstituted C1 to C20 oxyalkylene group as a linking group and an amine group as a substituent at the terminal end or a C6 to C20 aryloxy group having an amine group as a substituent at the terminal end.

### (A) Colorant

The photosensitive resin composition of some example embodiments may be a pigment-type photosensitive resin composition, and the colorant may include, e.g., a pigment. Color filters made from pigment-type photosensitive resin compositions could have limitations in luminance and contrast ratio resulting from the size of the pigment particles.

In an implementation, in order to be applied to image sensors, a resin composition made of smaller particles may be used to form fine patterns. To achieve this, a compound and a composition using the same may be included to help disperse the pigment and help prevent re-agglomeration.

The dispersion aid represented by Chemical Formula 1 may have a phthalocyanine parent nucleus and an amine group asymmetrically substituted with respect to the phthalocyanine parent nucleus.

The phthalocyanine parent nucleus may interact with the pigment, and the sulfonate salt asymmetrically substituted with respect to the phthalocyanine parent nucleus may interact with the dispersant or dispersing resin. Accordingly, the dispersion aid represented by Chemical Formula 1 may help increase the dispersibility and dispersion stability of the pigment by assisting the dispersant in the photosensitive resin composition.

In an implementation, the phthalocyanine parent nucleus may express a blue color. Accordingly, the dispersion aid represented by Chemical Formula 1 may help to increase coloring power by assisting the colorant in the photosensitive resin composition.

In an implementation, the dispersion aid represented by Chemical Formula 1 may be a dispersion aid that helps improve the dispersibility and dispersion stability of the pigment by assisting the dispersant, and functions to help increase coloring power by assisting the colorant. Accordingly, if the photosensitive resin composition including the dispersion aid represented by Chemical Formula 1 is implemented into a color filter and a display device, further improved coloring power (color gamut) and contrast ratio may be exhibited.

In an implementation, R¹¹ to R¹⁴ may each independently be, e.g., a hydrogen atom, a halogen atom, a hydroxy group, or a substituted or unsubstituted C1 to C20 alkyl group.

In an implementation, R¹¹ to R¹⁴ may be, e.g., all hydrogen atoms or may all be halogen atoms. In an implementation, the halogen atom may be, e.g., a chlorine atom.

In an implementation, R²¹ to R²⁴ may each independently be, e.g., a hydrogen atom, a halogen atom, a hydroxy group, or a substituted or unsubstituted C1 to C20 alkyl group.

In an implementation, R²¹ to R²⁴ may be all hydrogen atoms. In an implementation, one of R²¹ to R²⁴ may be, e.g., a substituted or unsubstituted C1 to C20 alkyl group, and the others may be all hydrogen atoms. In an implementation, one or two of R²¹ to R²⁴ may be, e.g., a branched C4 alkyl group (tert-butyl group), and the rest may be all hydrogen atoms.

In contrast to the case where all of R²¹ to R²⁴ are hydrogen atoms, if one or both of R²¹ to R²⁴ are branched C4 alkyl groups (tert-butyl groups), solubility of the dispersion aid represented by Chemical Formula 1 in the solvent may be improved.

The number of branched C4 alkyl groups (tert-butyl groups) among R²¹ to R²⁴ may depend on the number of N-containing substituents (A) in the dispersion aid represented by Chemical Formula 1. If the number of N-containing substituents (A) in the dispersion aid represented by Chemical Formula 1 is 1, the number of branched C4 alkyl groups (tert-butyl groups) among R²¹ to R²⁴ may also be 1. In an implementation, if there are two N-containing substituents (A) in the dispersion aid represented by Chemical Formula 1, there may also be two branched C4 alkyl groups (tert-butyl groups) among R²¹ to R²⁴. In an implementation, if there are three or more branched C4 alkyl groups (tert-butyl groups) among R²¹ to R²⁴, the chemical resistance of the dispersion aid represented by Chemical Formula 1 may be reduced.

In an implementation, R³¹ to R³⁴ may each independently be, e.g., a hydrogen atom, a halogen atom, a hydroxy group, or a substituted or unsubstituted C1 to C20 alkyl group.

In an implementation, R³¹ to R³⁴ may be, e.g., all hydrogen atoms.

In an implementation, one of R⁴¹ to R⁴⁴ may be, e.g., represented by Chemical Formula L-1 or Chemical Formula L-2.

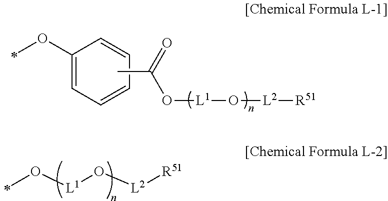

In Chemical Formula L-1 or Chemical Formula L-2, L¹ and L² may each independently be, e.g., a substituted or unsubstituted C1 to C20 alkylene group.

R⁵¹ may be, e.g., a substituted or unsubstituted amine group.

n may be, e.g., an integer of 0 to 10.

An amine group asymmetrically substituted for the phthalocyanine nucleus may be, e.g., represented as R⁵¹ in Chemical Formulae L-1 and L-2. In an implementation, there may be at least one amine group asymmetrically substituted with respect to the phthalocyanine parent nucleus. This is explained in detail as follows.

In an implementation, R⁵¹ may be, e.g., represented by Chemical Formula N.

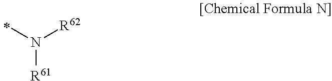

In Chemical Formula N, R⁶¹ and R⁶² may each independently be, e.g., a hydrogen atom, a substituted or unsubstituted C1 to C20 alkyl group, a substituted or unsubstituted C3 to C20 cycloalkyl group, a substituted or unsubstituted C6 to C20 aryl group, or a substituted or unsubstituted C2 to C20 heterocyclic group, wherein R⁶¹ and R⁶² may each separately be present or may be linked to each other to form a fused ring.

In an implementation, R⁵¹ may be, e.g., represented by one of Chemical Formula N-1 to Chemical Formula N-6.

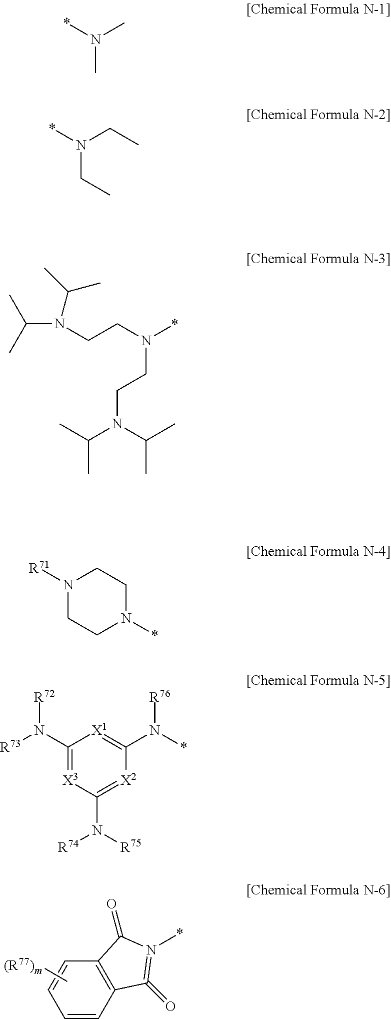

In Chemical Formula N-4 to Chemical Formula N-6, X¹ to X³ may each independently be, e.g., N or CH.

R⁷¹ to R⁷⁷ may each independently be, e.g., a hydrogen atom, a substituted or unsubstituted C1 to C20 alkyl group, a substituted or unsubstituted C3 to C20 cycloalkyl group, a substituted or unsubstituted C6 to C20 aryl group, or a substituted or unsubstituted C2 to C20 heterocyclic group.

m may be, e.g., an integer of 0 to 4.

The dispersion aid represented by Chemical Formula 1 may have an amine group of the structure as a substituent, and because the amine group of the structure may be linked to the phthalocyanine parent nucleus by a linking group including an “ester group and an oxyalkylene group” or an “ether group and an oxyalkylene group” (e.g., refer to the structures of Chemical Formulae L-1 and L-2), it may have excellent dispersibility and dispersion stability, while at the same time helping improve the coloring power and contrast ratio.

In an implementation, the dispersion aid represented by Chemical Formula 1 may be, e.g., represented by one of Chemical Formulae 1-1 to 1-13.

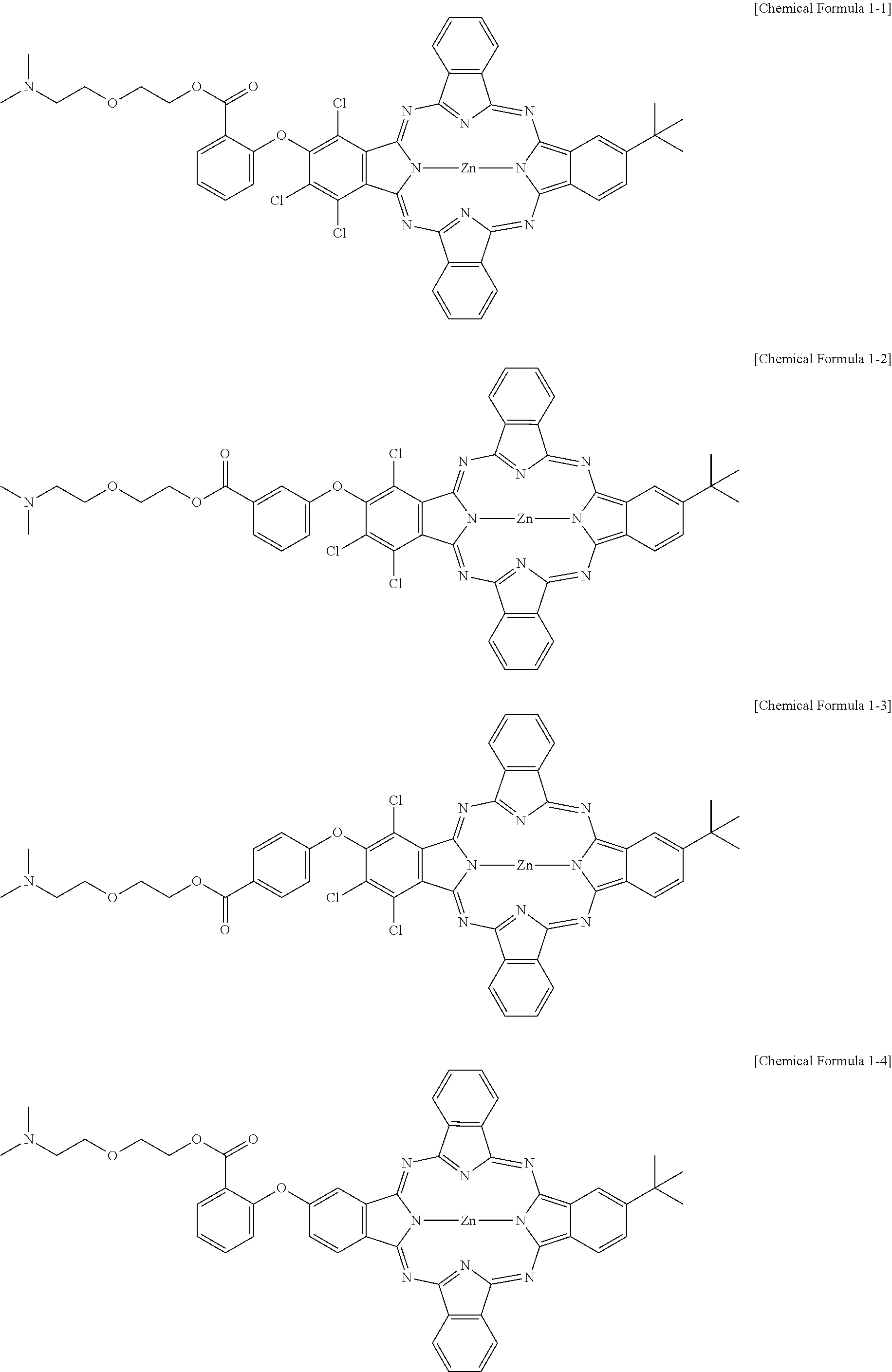

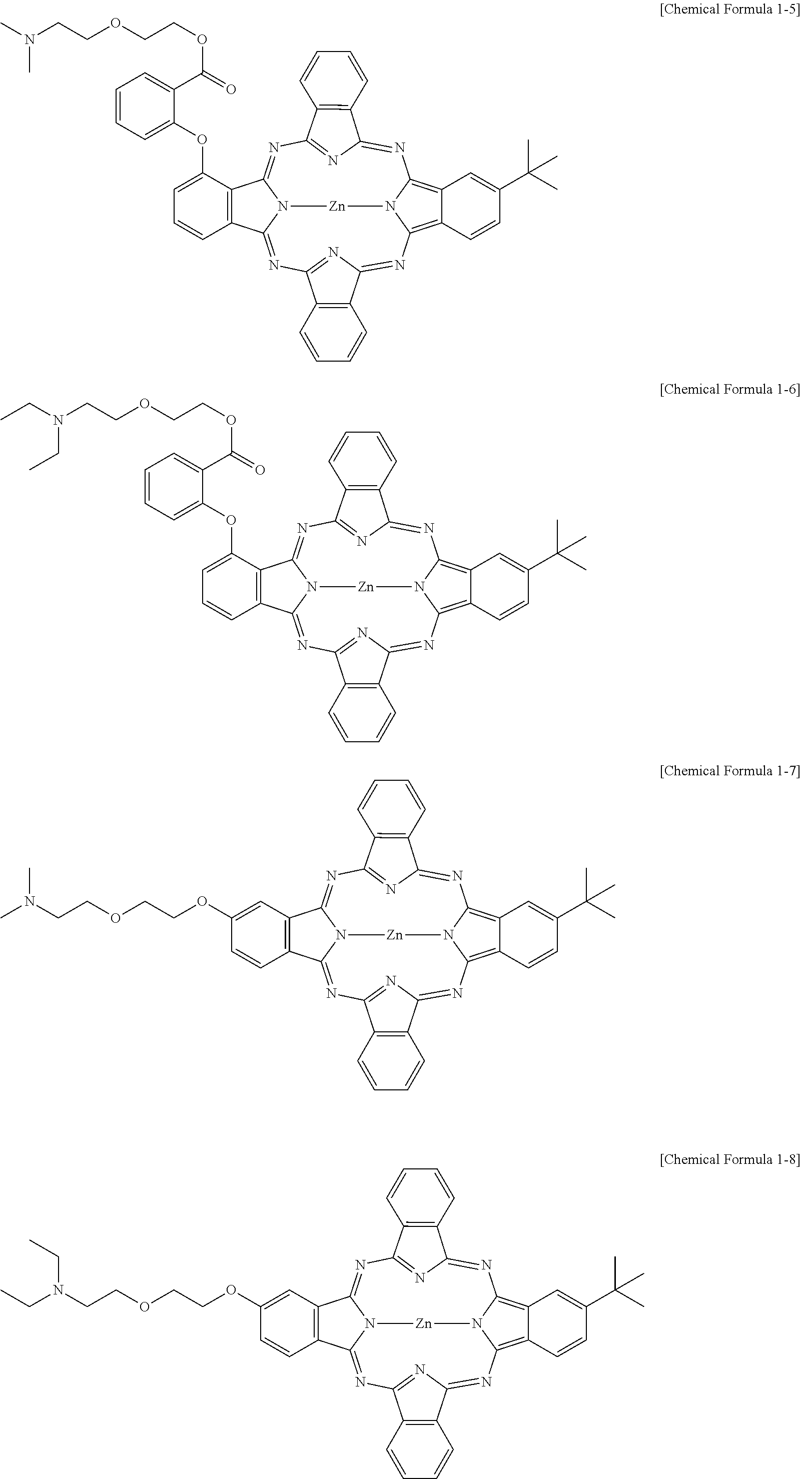

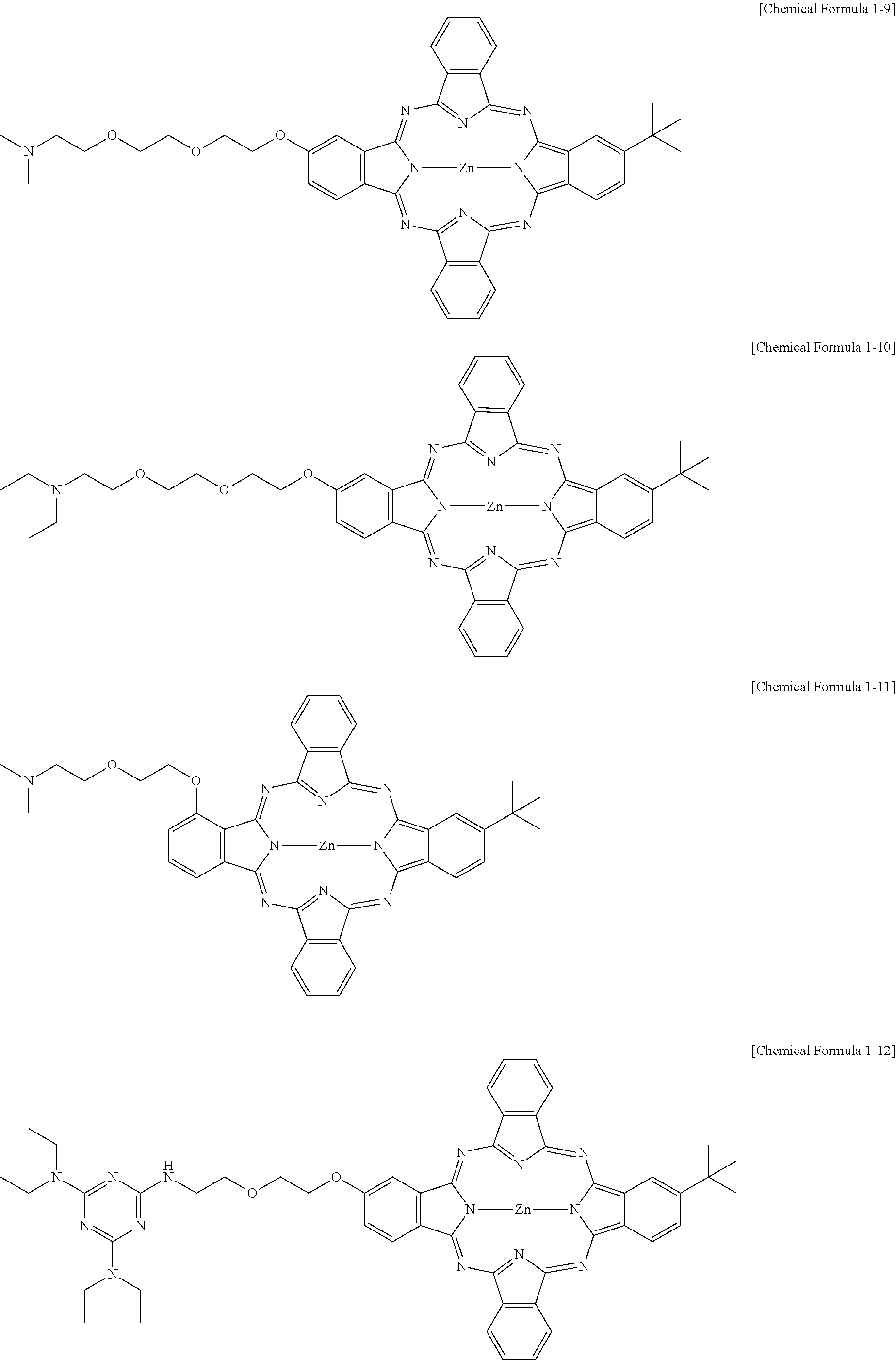

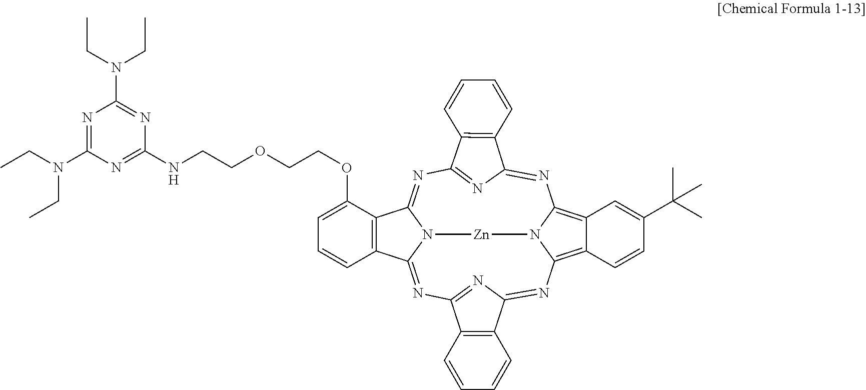

The dispersion aid represented by Chemical Formula 1 may have, e.g., a phthalocyanine parent nucleus that expresses a blue color, and may help further improve the coloring power and contrast ratio of the photosensitive resin composition.

In an implementation, the dispersion aid represented by Chemical Formula 1 may have a maximum absorption wavelength (λₘₐₓ) of, e.g., about 450 nm to about 495 nm.

The dispersion aid represented by Chemical Formula 1 may be included in an amount of, e.g., 3 wt % to 8 wt %, 4 wt % to 7 wt %, or 5 wt % to 7 wt %, based on the total weight of solid content constituting the photosensitive resin composition. The dispersing aid represented by Chemical Formula 1 may be included in an amount of, e.g., about 3 wt % to about 8 wt %, about 4 wt % to about 7 wt %, or about 5 wt % to about 7 wt %, based on a total solid content of the photosensitive resin composition.

In an implementation, a weight ratio of the dispersion aid represented by Chemical Formula 1 and the pigment may be, e.g., about 1:3 to about 1:14, about 1:4 to about 1:10, about 1:4 to about 1:9, or about 1:4 to about 1:8.

Within each of the above ranges, the dispersibility and dispersion stability of the photosensitive resin composition according to the above embodiment may be improved while the coloring power and contrast ratio may be improved.

The colorant may include a pigment, and the pigment may include a green pigment, a blue pigment, a red pigment, a violet pigment, a yellow pigment, or a black pigment.

The red pigment may include, e.g., C.I. Red Pigment 254, C.I. Red Pigment 255, C.I. Red Pigment 264, C.I. Red Pigment 270, C.I. Red Pigment 272, C.I. Red Pigment 177, C.I. Red Pigment 89, or the like in the color index, which may be used alone or in a mixture of two or more.

The violet pigment may include, e.g., C.I. Violet Pigment 23 (V23), C.I. Violet Pigment 29, Dioxazine Violet, First Violet B, Methyl Violet Lake, Indanethrene Brilliant Violet, or the like in the color index, which may be used alone or in a mixture of two or more.

The green pigment may include, e.g., C.I. Green Pigment 7, C.I. Green Pigment 36, C.I. Green Pigment 58, C.I. Green Pigment 59, or the like in the color index, which may be used alone or in a mixture of two or more.

The blue pigment may include, e.g., copper phthalocyanine pigments such as C.I. Blue Pigment 15:6, C.I. Blue Pigment 15, C.I. Blue Pigment 15:1, C.I. Blue Pigment 15:2, C.I. Blue Pigment 15:3, C.I. Blue Pigment 15:4, C.I. Blue Pigment 15:5, C.I. Blue Pigment 15:6, C.I. Blue Pigment 16, or the like in the color index, which may be used alone or in a mixture of two or more.

The yellow pigment may include, e.g., an isoindoline pigment such as C.I. Yellow Pigment 185, C.I. Yellow Pigment 139, or the like, a quinophthalone pigment such as C.I. Yellow Pigment 138, a nickel complex pigment such as C.I. Yellow Pigment 150 in the color index, which may be used alone or in a mixture of two or more.

The black pigment may include, e.g., aniline black, perylene black, titanium black, carbon black, or the like in the color index, which may be used alone or in a mixture of two or more.

The pigment may be used alone or in a mixture of two or more. In an implementation, the pigment may be a green pigment, a yellow pigment, or a mixture thereof.

The dispersant may help to uniformly disperse the pigment, and may include, e.g., a non-ionic, anionic, or cationic dispersant. Examples may be, e.g., polyalkylene glycol or esters thereof, polyoxy alkylene, polyhydric alcohol ester alkylene oxide addition products, alcohol alkylene oxide addition products, sulfonate esters, sulfonate salts, carboxylate esters, carboxylate salts, alkyl amide alkylene oxide addition products, alkyl amines, or the like, and these may be used alone or as a mixture of two or more.

The pigment may be included in the photosensitive resin composition for a color filter in the form of a dispersion. This pigment dispersion may further include, e.g., a dispersion solvent, a dispersion binder, or the like in addition to the pigment, the dispersant, and the dispersion aid. The pigment in the solid content excluding the solvent may be included in an amount of about 50 wt % to about 80 wt %, about 60 wt % to about 70 wt %, based on the total weight of solid content constituting the pigment dispersion.

A solvent for the pigment dispersion may include, e.g., ethylene glycol acetate, ethyl cellosolve, propylene glycol methyl ether acetate, ethyl lactate, polyethylene glycol, cyclohexanone, propylene glycol methyl ether, or the like. In an implementation, the solvent may include, e.g., propylene glycol methyl ether acetate.

The dispersion binder may be an acrylic including a carboxyl group, which may help improve stability of the pigment dispersion and pattern properties of a pixel.

The colorant may include the pigment and may further include a dye, and in this case, the resin composition of some example embodiments may be a hybrid type composition. In an implementation, the dye may include a metal complex dye.

The metal complex dye may be a compound having maximum absorbance in the wavelength range of 200 nm to 650 nm. If the compound has absorbance in the above range in order to match the color coordinates to the combination of dyes, the metal complex dye of all colors that dissolves in an organic solvent may be used.

In an implementation, the metal complex dye may be, e.g., a green dye having maximum absorbance in a wavelength range of 530 nm to 680 nm, a yellow dye having maximum absorbance in a wavelength range of 200 nm to 400 nm, an orange dye having a maximum absorbance in a wavelength range of 300 nm to 500 nm, a red dye having maximum absorbance in a wavelength range of 500 nm to 650 nm, or a combination thereof.

The metal complex dye may be, e.g., a direct dye, an acidic dye, a basic dye, an acidic mordant dye, a sulfide dye, a reduction dye, an azoic dye, a dispersion dye, a reactive dye, an oxidation dye, an oil-soluble dye, an azo dye, an anthraquinone dye, an indigoid dye, a carbonium ion dye, a phthalocyanine dye, a nitro dye, a quinoline dye, a cyanine dye, a polymethine dye, or a combination thereof.

The metal complex dye may include, e.g., one metal ion selected from Mg, Ni, Cu, Co, Zn, Cr, Pt, Pd, or Fe.

The metal complex dye may be a complex of, e.g., C.I. Solvent Dye such as C.I. Solvent Green 1, 3, 4, 5, 7, 28, 29, 32, 33, 34, 35, or the like; C.I. Acid Dye such as C.I. Acid Green 1, 3, 5, 6, 7, 8, 9, 11, 13, 14, 15, 16, 22, 25, 27, 28, 41, 50, 50:1, 58, 63, 65, 80, 104, 105, 106, 109, or the like; C.I. Direct Dye such as C.I. Direct Green 25, 27, 31, 32, 34, 37, 63, 65, 66, 67, 68, 69, 72, 77, 79, 82, or the like; C.I. Basic Dye such as C.I. Basic Green 1, or the like; C.I. Mordant Dye such as C.I. Mordant Green 1, 3, 4, 5, 10, 13, 15, 19, 21, 23, 26, 29, 31, 33, 34, 35, 41, 43, 53, or the like; C.I. Green pigments such as Pigment Green 7, 36, 58, or the like; Solvent Yellow 19, Solvent Yellow 21, Solvent Yellow 25, Solvent Yellow 79, Solvent Yellow 82, Solvent Yellow 88, Solvent Orange 45, Solvent Orange 54, Solvent Orange 62, Solvent Orange 99, Solvent Red 8, Solvent Red 32, Solvent Red 109, Solvent Red 112, Solvent Red 119, Solvent Red 124, Solvent Red 160, Solvent Red 132, or Solvent Red 218, and the metal ion.

The metal complex dye may have a solubility of greater than or equal to 5, e.g., 5 to 10, in a solvent used in the photosensitive resin composition according to some embodiments. The solubility may be obtained by an amount (g) of the dye dissolved in 100 g of the solvent. If the solubility of the metal complex dye is within the above ranges, compatibility with other components constituting the photosensitive resin composition according to some embodiments and coloring power may be secured, and precipitation of the dye may be prevented.

The solvent may include, e.g., propylene glycol monomethyl ether acetate (PGMEA), ethyl lactate (EL), ethylene glycol ethyl acetate (EGA), cyclohexanone, 3-methoxy-1-butanol, or a combination thereof.

In an implementation, it may be usefully used for color filters such as LCDs and LEDs that express high luminance and high contrast ratio in a desired color coordinate.

The metal complex dye may be included in an amount of about 0.01 wt % to about 1 wt %, e.g., about 0.01 wt % to about 0.5 wt %, based on a total weight of the photosensitive resin composition. If the metal complex dye is used in the above ranges, high luminance and contrast ratio can be exhibited in a desired color coordinate.

When the dye and the pigment are mixed and used, they may be mixed in a weight ratio of about 0.1:99.9 to about 99.9:0.1, e.g., about 1:9 to about 9:1. If mixed in the above weight ratio range, chemical resistance and maximum absorption wavelength may be controlled within an appropriate range, and high luminance and contrast ratio may be exhibited in a desired color coordinate.

The colorant may be included in an amount of about 30 wt % to about 70 wt %, e.g., about 35 wt % to about 65 wt % or about 40 wt % to about 60 wt %, based on a total solid content of the photosensitive resin composition. If the colorant is included within the above ranges, a coloring effect and developability are improved.

### (B) Photopolymerizable Compound

The photopolymerizable compound may be, e.g., a mono-functional or multi-functional ester of (meth)acrylic acid including at least one ethylenic unsaturated double bond.

The photopolymerizable compound may help facilitate sufficient polymerization during exposure in a pattern-forming process and form a pattern having excellent heat resistance, light resistance, and chemical resistance due to the ethylenic unsaturated double bond.

In an implementation, the photopolymerizable compound may be, e.g., ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolac epoxy (meth)acrylate, or the like.

Commercially available examples of the photopolymerizable compound may be as follows. The mono-functional (meth)acrylic acid ester may include Aronix M-101®, M-111®, M-114® (Toagosei Chemistry Industry Co., Ltd.); KAYARAD TC-110S®, TC-120S® (Nippon Kayaku Co., Ltd.); V-158®, V-2311® (Osaka Organic Chemical Ind., Ltd.), or the like. Examples of a difunctional (meth)acrylic acid ester may include Aronix M-210®, M-240®, M-6200® (Toagosei Chemistry Industry Co., Ltd.), KAYARAD HDDA®, HX-220®, R-604® (Nippon Kayaku Co., Ltd.), V-260®, V-312®, V-335 HP® (Osaka Organic Chemical Ind., Ltd.), or the like. Examples of a tri-functional (meth)acrylic acid ester may include Aronix M-309®, M-400®, M-405®, M-450®, M-7100®, M-8030®, M-8060® (Toagosei Chemistry Industry Co., Ltd.), KAYARAD TMPTA®, DPCA-20®, DPCA-30®, DPCA-60®, DPCA-120® (Nippon Kayaku Co., Ltd.), V-295®, V-300®, V-360®, V-GPT®, V-3PA®, V-400® (Osaka Yuki Kayaku Kogyo Co. Ltd.), or the like. These may be used alone or as a mixture of two or more.

The photopolymerizable compound may be treated with acid anhydride to help improve developability.

The photopolymerizable compound may be included in an amount of about 1 wt % to about 20 wt %, e.g., about 3 wt % to about 15 wt %, about 5 wt % to about 15 wt %, based on a total solid content of the photosensitive resin composition. If the photopolymerizable compound is included within the above ranges, sufficient curing may occur during exposure to light in the pattern formation process, resulting in excellent reliability and excellent developability in an alkaline developer.

### (C) Photopolymerization Initiator

The photopolymerization initiator may be a suitable photopolymerization initiator in a photosensitive resin composition, e.g., an acetophenone compound, a benzophenone compound, a thioxanthone compound, a benzoin compound, an oxime compound, or the like.

Examples of the acetophenone compound may include 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, or the like.

Examples of the benzophenone compound may include benzophenone, benzoyl benzoate, methyl benzoyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, or the like.

Examples of the thioxanthone compound may include thioxanthone, 2-methylthioxanthone, isopropyl thioxanthone, 2,4-diethyl thioxanthone, 2,4-diisopropyl thioxanthone, 2-chlorothioxanthone, or the like.

Examples of the benzoin compound may include benzoin, benzoin methyl ether, benzoin ethyl ether, benzoin isopropyl ether, benzoin isobutyl ether, benzyldimethylketal, or the like.

Examples of the triazine compound may include 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloro methyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, or the like.

Examples of the oxime-based compound may be O-acyloxime compound, 2-(O-benzoyloxime)-1-[4-(phenylthio)phenyl]-1,2-octandione, 1-(O-acetyloxime)-1-[9-ethyl-6-(2-methylbenzoyl)-9H-carbazol-3-yl]ethanone, O-ethoxycarbonyl-α-oxyamino-1-phenylpropan-1-one, or the like. Specific examples of the O-acyloxime compound may be 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione 2-oxime-O-benzoate, 1-(4-phenylsulfanyl phenyl)-octane-1,2-dione 2-oxime-O-benzoate, 1-(4-phenylsulfanyl phenyl)-octan-1-one oxime-O-acetate, 1-(4-phenylsulfanyl phenyl)-butan-1-one oxime-O-acetate, or the like.

The photopolymerization initiator may further include a carbazole compound, a diketone compound, a sulfonium borate compound, a diazo compound, an imidazole compound, a biimidazole compound, a fluorene compound, or the like, in addition to the other compounds.

The photopolymerization initiator may be used with a photosensitizer capable of causing a chemical reaction by absorbing light and becoming excited and then transferring its energy.

Examples of the photosensitizer may include tetraethylene glycol bis-3-mercapto propionate, pentaerythritol tetrakis-3-mercapto propionate, dipentaerythritol tetrakis-3-mercapto propionate, or the like.

The photopolymerization initiator may be included in an amount of about 0.1 wt % to about 5 wt %, e.g., about 1 wt % to about 3 wt %, based on a total solid content of the photosensitive resin composition. If the photopolymerization initiator is included within the range, excellent reliability may be secured due to sufficiently curing during exposure in a pattern-forming process, a pattern may have excellent resolution and close-contacting properties as well as excellent heat resistance, light resistance, and chemical resistance, and transmittance may be prevented from deterioration due to a non-reaction initiator.

### (D) Binder Resin

The binder resin may include an acrylic binder resin.

The acrylic resin may be, e.g., a copolymer of a first ethylenic unsaturated monomer and a second ethylenic unsaturated monomer that is copolymerizable therewith, and is a resin including at least one acryl repeating unit.

The first ethylenic unsaturated monomer may be an ethylenic unsaturated monomer including at least one carboxyl group and examples of the monomer may include acrylic acid, methacrylic acid, maleic acid, itaconic acid, fumaric acid, or a combination thereof.

The first ethylenic unsaturated monomer may be included in an amount of about 5 wt % to about 50 wt %, e.g., about 10 wt % to about 40 wt %, based on a total weight of the acrylic binder resin.

The second ethylenic unsaturated monomer may include, e.g., an aromatic vinyl compound such as styrene, α-methylstyrene, vinyl toluene, vinylbenzylmethylether or the like; an unsaturated carboxylate ester compound such as methyl(meth)acrylate, ethyl(meth)acrylate, butyl(meth)acrylate, 2-hydroxyethyl(meth)acrylate, 2-hydroxy butyl(meth)acrylate, benzyl(meth)acrylate, cyclohexyl(meth)acrylate, phenyl(meth)acrylate, or the like; an unsaturated amino alkyl carboxylate ester compound such as 2-aminoethyl(meth)acrylate, 2-dimethylaminoethyl(meth)acrylate, or the like; a carboxylic acid vinyl ester compound such as vinyl acetate, vinyl benzoate, or the like; an unsaturated glycidyl carboxylate ester compound such as glycidyl(meth)acrylate, or the like; a vinyl cyanide compound such as (meth)acrylonitrile or the like; an unsaturated amide compound such as (meth)acrylamide, or the like; or the like, and may be used alone or as a mixture of two or more.

In an implementation, the acrylic resin may be, e.g., a (meth)acrylic acid/benzylmethacrylate copolymer, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, or the like, and these may be used alone or as a mixture of two or more.

The binder resin may include an epoxy resin.

The binder resin may improve heat resistance by further including an epoxy resin. The epoxy resin may be, e.g., a phenol novolac epoxy resin, a tetramethyl biphenyl epoxy resin, a bisphenol A epoxy resin, a bisphenol F epoxy resin, an alicyclic epoxy resin, or a combination thereof.

Furthermore, the binder resin including the epoxy resin may help secure dispersion stability of a colorant such as a pigment, and may help form a pixel having a desired resolution during a developing process.

The epoxy resin may be included in an amount of about 1 wt % to about 10 wt %, e.g., about 5 wt % to about 10 wt %, based on a total weight of the binder resin. If the epoxy resin is included in the above ranges, film residue ratio and chemical resistance may be greatly improved.

An epoxy equivalent weight of the epoxy resin may be 150 g/eq to 200 g/eq. If an epoxy resin having an epoxy equivalent within the above ranges is included in the binder resin, there may be an advantageous effect in improving a curing degree of the formed pattern and fixing the colorant in the structure in which the pattern is formed.

The binder resin may be dissolved in a solvent in a solid form to form a photosensitive resin composition. In this case, the binder resin in the solid form may be included in an amount of about 0.1 wt % to about 30 wt %, e.g., about 20 wt % to about 30 wt %, based on a total weight of the binder resin solution dissolved in the solvent.

In an implementation, the binder resin may be included in an amount of, e.g., about 0.5 wt % to about 10 wt %, about 1 wt % to about 7 wt %, or about 1 wt % to about 5 wt %, based on a total solid content of the photosensitive resin composition. If the binder resin is included within the above range, it may be possible to obtain excellent surface smoothness due to excellent developability and improved crosslinking property during manufacture of the color filter.

### (E) Solvent

The solvent may be a material having compatibility with the colorant, the binder resin, the photopolymerizable compound, and the photopolymerization initiator but not reacting therewith.

Examples of the solvent may include, e.g., alcohols such as methanol, ethanol, or the like; ethers such as dichloroethyl ether, n-butyl ether, diisoamyl ether, methylphenyl ether, tetrahydrofuran, or the like; glycol ethers such as ethylene glycol monomethylether, ethylene glycol monoethylether, or the like; cellosolve acetates such as methyl cellosolve acetate, ethyl cellosolve acetate, diethyl cellosolve acetate, or the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, or the like; propylene glycol alkylether acetates such as propylene glycol monomethylether acetate, propylene glycol propylether acetate, or the like; aromatic hydrocarbons such as toluene, xylene or the like; ketones such as methylethylketone, cyclohexanone, 4-hydroxy-4-methyl-2-pentanone, methyl-n-propylketone, methyl-n-butylketone, methyl-n-amylketone, 2-heptanone, or the like; saturated aliphatic monocarboxylic acid alkyl esters such as ethyl acetate, n-butyl acetate, isobutyl acetate, or the like; lactate esters such as methyl lactate, ethyl lactate, or the like; oxy acetic acid alkyl esters such as oxy methyl acetate, oxy ethyl acetate, butyl oxyacetate, or the like; alkoxy acetic acid alkyl esters such as methoxy methyl acetate, methoxy ethyl acetate, methoxy butyl acetate, ethoxy methyl acetate, ethoxy ethyl acetate, or the like; 3-oxy propionic acid alkyl esters such as 3-oxy methyl propionate, 3-oxy ethyl propionate, or the like; 3-alkoxy propionic acid alkyl esters such as 3-methoxy methyl propionate, 3-methoxy ethyl propionate, 3-ethoxy ethyl propionate, 3-ethoxy methyl propionate, or the like; 2-oxy propionic acid alkyl esters such as 2-oxy methyl propionate, 2-oxy ethyl propionate, 2-oxy propyl propionate, or the like; 2-alkoxy propionic acid alkyl esters such as 2-methoxy methyl propionate, 2-methoxy ethyl propionate, 2-ethoxy ethyl propionate, 2-ethoxy methyl propionate, or the like; 2-oxy-2-methyl propionic acid esters such 2-oxy-2-methyl methyl propionate, 2-oxy-2-methyl ethyl propionate, or the like, monooxy monocarboxylic acid alkyl esters of 2-alkoxy-2-methyl alkyl propionates such as 2-methoxy-2-methyl methyl propionate, 2-ethoxy-2-methyl ethyl propionate, or the like; esters such as 2-hydroxy ethyl propionate, 2-hydroxy-2-methyl ethyl propionate, hydroxy ethyl acetate, 2-hydroxy-3-methyl methyl butanoate, or the like; ketonate esters such as ethyl pyruvate, or the like. In an implementation, a high boiling point solvent such as N-methylformamide, N,N-dimethylformamide, N-methylformanilide, N-methylacetamide, N,N-dimethylacetamide, N-methylpyrrolidone, dimethylsulfoxide, benzylethylether, dihexylether, acetylacetone, isophorone, caproic acid, caprylic acid, 1-octanol, 1-nonanol, benzylalcohol, benzyl acetate, ethyl benzoate, diethyl oxalate, diethyl maleate, γ-butyrolactone, ethylene carbonate, propylene carbonate, phenyl cellosolve acetate, or the like may be also used.

In an implementation, considering compatibility and reactivity, the solvents including propylene glycol monomethyl ether acetate (PGMEA), n-butyl acetate (n-BA), and ethylene glycol dimethyl ether, or a combination thereof may be used.

The solvent may be included in a balance amount, e.g., about 40 wt % to about 90 wt % or about 45 wt % to about 70 wt %, based on a total weight of the photosensitive resin composition. The solvent may be included in an amount of 3 to 7 times the total weight of solids constituting the photosensitive resin composition. If the solvent is included within these ranges, coating properties of the photosensitive resin composition may be improved and a film having improved flatness may be obtained.

### (F) Other Additives

The photosensitive resin composition may further include an additive, e.g., malonic acid; 3-amino-1,2-propanediol; a coupling agent; a leveling agent; a surfactant; an antioxidant; or a combination thereof in order to help prevent stains or spots during the coating, to help adjust leveling, or to help prevent pattern residue due to non-development.

The additives may be easily adjusted according to desired physical properties.

The coupling agent may include, e.g., a silane coupling agent, and examples of the silane coupling agent may include, e.g., trimethoxysilyl benzoic acid, γ methacryl oxypropyl trimethoxysilane, vinyl triacetoxysilane, vinyl trimethoxysilane, γ isocyanate propyl triethoxysilane, γ glycidoxy propyl trimethoxysilane, β (epoxycyclohexyl) ethyltrimethoxysilane, which may be used alone or in mixture of 2 or more types.

The silane coupling agent may be included in an amount of, e.g., about 0.01 part by weight to about 1 part by weight, based on 100 parts by weight of the photosensitive resin composition.

In an implementation, the photosensitive resin composition for a color filter may further include a surfactant, e.g., a fluorine surfactant.

Examples of the fluorine surfactant include, but are not limited to, F-482, F-484, and F-478 of DIC Co., Ltd.

The surfactant may be included in an amount of, e.g., about 0.01 wt % to about 5 wt % or about 0.01 wt % to about 2 wt %, based on a total weight of the photosensitive resin composition. If the surfactant is included in the above ranges, generation of foreign substances after development may be avoided.

In an implementation, other additives, e.g., an antioxidant, a stabilizer, or the like may be added to the photosensitive resin composition within an amount that does not impair physical properties.

The antioxidant may include, e.g., a hydroquinone compound, a catechol compound, or a combination thereof. In an implementation, if the photosensitive resin composition further includes the hydroquinone compound, the catechol compound, or a combination thereof, crosslinking at room temperature may be prevented during exposure after printing (coating) the photosensitive resin composition.

In an implementation, the hydroquinone compound, catechol compound, or combination thereof may include, e.g., hydroquinone, methyl hydroquinone, methoxyhydroquinone, t-butyl hydroquinone, 2,5-di-t-butyl hydroquinone, 2,5-bis(1,1-dimethylbutyl)hydroquinone, 2,5-bis(1,1,3,3-tetramethylbutyl)hydroquinone, catechol, t-butyl catechol, 4-methoxyphenol, pyrogallol, 2,6-di-t-butyl-4-methylphenol, 2-naphthol, tris(N-hydroxy-N-nitrosophenylaminato-O,O′)aluminium, or a combination thereof.

The hydroquinone compound, catechol compound, or a combination thereof may be used in the form of a dispersion, and the antioxidant in the form of the dispersion may be included in an amount of about 0.001 wt % to about 3 wt %, e.g., about 0.1 wt % to about 2 wt %, based on a total solid content of the photosensitive resin composition. If the antioxidant is included within the above ranges, aging at ambient temperature may be avoided while preventing sensitivity degradation and surface peeling.

### (Photosensitive Resin Film, Color Filter, and Display Device)

According to some example embodiments, a photosensitive resin film manufactured using the photosensitive resin composition according to some example embodiments may be provided.

The photosensitive resin film of some example embodiments may be divided into a positive photoresist composition and a negative photoresist composition.

The photosensitive resin film of some example embodiments may be a negative photoresist. This may have the advantage that coloring caused by the photoresist may not occur and that light sensitivity may be relatively higher than that of positive photoresist.

In an implementation, a color filter may be manufactured using the aforementioned photosensitive resin composition.

A method of manufacturing the color filter according to some example embodiments is as follows.

The aforementioned photosensitive resin composition is coated to form a photosensitive resin composition layer with a thickness of about 0.3 um to about 0.5 um on a glass substrate using a method such as spin coating, roller coating, spray coating, or the like.

Subsequently, the substrate having the photosensitive resin composition layer may be irradiated by light or other radiation to form a pattern required for a color filter. The irradiation may be performed by using UV, an electron beam, or an X-ray as a light source or radiation source, and the UV may be irradiated, e.g., in a region of about 190 nm to about 450 nm or about 200 nm to about 400 nm. The irradiation may be performed by further using a photoresist mask. After performing the irradiation process in this way, the photosensitive resin composition layer exposed to the light source may be treated with a developer. An unexposed region in the photosensitive resin composition layer may be dissolved and may form the pattern for a color filter. This process may be repeated as many times as the number of colors, obtaining a color filter having a desired pattern. In an implementation, if the image pattern obtained through development in the above process is cured by reheating or radiating an actinic ray thereinto, crack resistance, solvent resistance, or the like may be improved.

According to some example embodiments, a display device including the aforementioned color filter is provided.

The display device may be a liquid crystal display device, a CMOS image sensor, or the like.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis Examples

### Synthesis Example 1: Compound Represented by Chemical Formula 1-1

### (1) Preparation of Intermediate 1-1-1

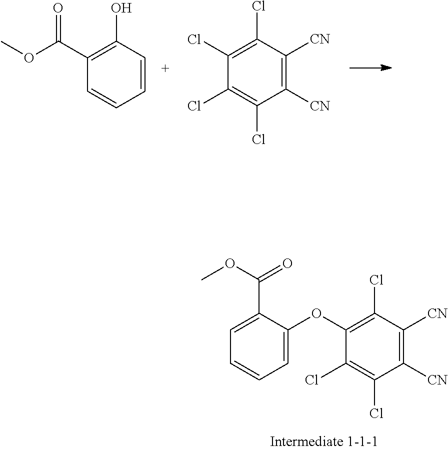 [SMILES: COC(=O)c1ccccc1O ; N#Cc1c(Cl)c(Cl)c(Cl)c(Cl)c1C#N ; COC(=O)c1ccccc1Oc1c(Cl)c(Cl)c(C#N)c(C#N)c1Cl]

Methyl salicylate (10 g), 3,4,5,6-tetrachlorophthalonitrile (17.5 g), K₂CO₃ (10.9 g), and N,N-dimethylformamide (DMF) (100 ml) were added to a 250 ml flask and stirred while heating to 70° C. After completion of the reaction, extraction was performed with EA (ethyl acetate). After extraction and concentration, it was purified by column chromatography. After purification and vacuum drying, Intermediate 1-1-1 was obtained.

### (2) Preparation of Intermediate 1-1-2

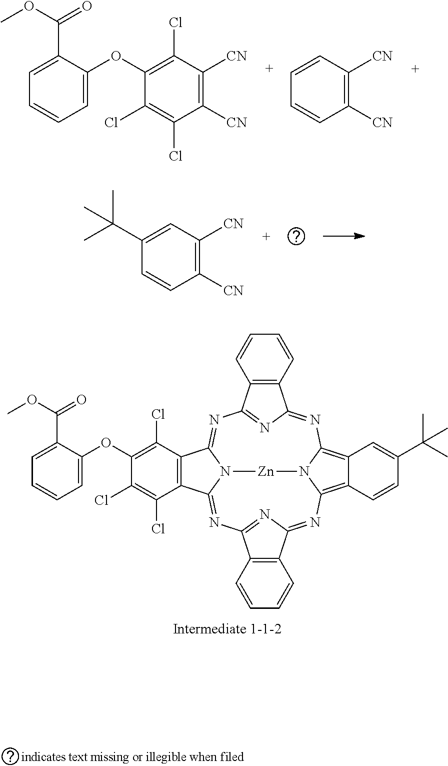

In a 100 mL flask, Intermediate 1-1-1 (4 g), phthalonitrile (1.34 g), 4-tert-butylphthalonitrile (1.93 g), 1,8-diazabicyclo[5.4.0]-7-undecene (3.19 g), and 1-pentenol (20 g) were added, then heated to 90° C., until the solids were dissolved, and zinc acetate (1.93 g) was added thereto and then stirred while heating at 140° C. After a reaction was completed, the resultant was precipitated with methanol, filtered, and dried under vacuum. The dried solid was purified by column chromatography. After the purification, an appropriate amount of MC (methylene chloride) was added to the obtained solid to dissolve the solid, and then methanol was added to crystallize it. The crystallized solid was filtered and vacuum-dried to obtain Intermediate 1-1-2.

### (3) Preparation of Compound Represented by Chemical Formula 1-1

In a 100 mL flask, Intermediate 1-1-2 (1.0 g), 2-[2-(dimethylamino)ethoxy]ethanol (0.30 g), and N,N-dimethylformamide (DMF) (10 ml) were added, and after connecting a condenser to the flask, an nitrogen atmosphere was provided. The resultant was stirred while heating to 100° C., and extracted with DIW (deionized water) and MC after the reaction was completed. The extracted organic layer was dehydrated with MgSO₄ and concentrated. After dissolving an appropriate amount of MC to the obtained solid, methanol was added to crystallize it. The crystallized solid was filtered and vacuum-dried to obtain a compound represented by Chemical Formula 1-1.

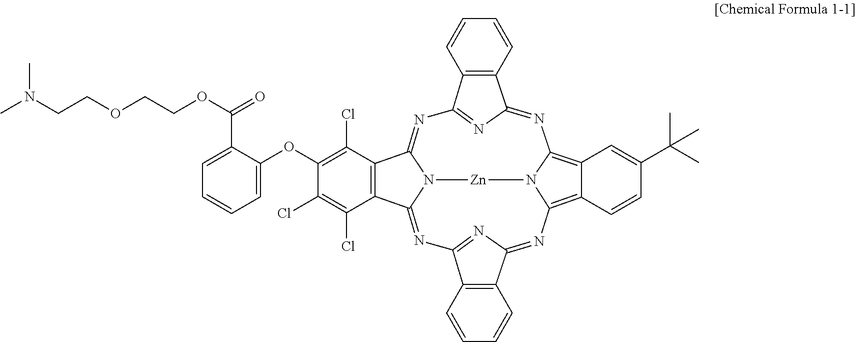

Maldi-tof MS: 986 m/z

### Synthesis Example 2: Compound Represented by Chemical Formula 1-2

### (1) Preparation of Intermediate 1-2-1

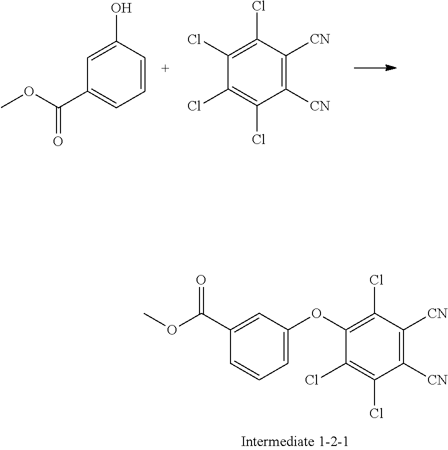 [SMILES: COC(=O)c1cccc(O)c1 ; N#Cc1c(Cl)c(Cl)c(Cl)c(Cl)c1C#N ; COC(=O)c1cccc(Oc2c(Cl)c(Cl)c(C#N)c(C#N)c2Cl)c1]

### Intermediate 1-2-1

In a 250 ml flask, methyl 3-hydroxybenzoate (10 g), 3,4,5,6-tetrachlorophthalonitrile (17.5 g), K₂CO₃ (10.9 g), and N,N-dimethylformamide (DMF) (100 ml) were added and then stirred while heating to 70° C. After completing a reaction, extraction was performed with EA (ethyl acetate). After extraction and concentration, it was purified by column chromatography. After purification and vacuum drying, Intermediate 1-2-1 was obtained.

### (2) Preparation of Intermediate 1-2-2

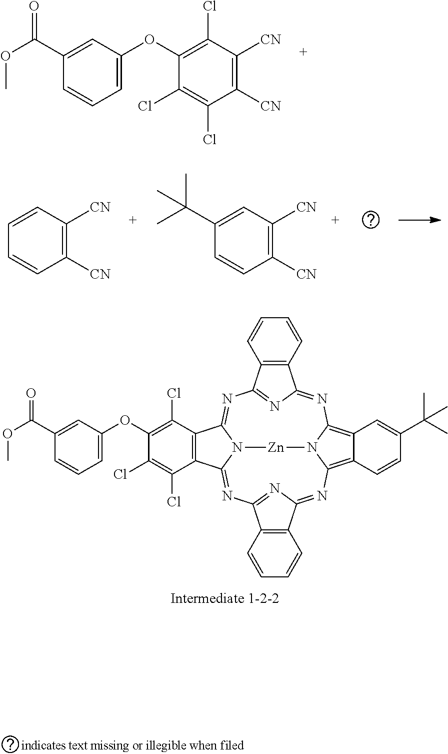

In a 100 mL flask, Intermediate 1-2-1 (4 g), phthalonitrile (1.34 g), 4-tert-butylphthalonitrile (1.93 g), 1,8-diazabicyclo[5.4.0]-7-undecene (3.19 g), and 1-pentenol (20 g) were added and then heated to 90° C., until the solids were dissolved, and zinc acetate (1.93 g) was added thereto and then stirred while heating at 140° C. After the reaction was completed, the resultant was precipitated with methanol, filtered, and dried under vacuum. The dried solid was purified by column chromatography. After purification, an appropriate amount of MC was added to the obtained solid to dissolve the solid, and then methanol was added to crystallize it. The crystallized solid was filtered and vacuum-dried to obtain Intermediate 1-2-2.

### (3) Preparation of Compound Represented by Chemical Formula 1-2

In a 100 mL flask, Intermediate 1-2-2 (1.0 g), 2-[2-(dimethylamino)ethoxy]ethanol (0.30 g), and N,N-dimethylformamide (DMF) (10 ml) were added, and after connecting a condenser to the flask, a nitrogen atmosphere was formed. The resultant was stirred while heating to 100° C., and extracted with DIW and MC after the reaction was completed. The extracted organic layer was dehydrated with MgSO₄ and concentrated. After dissolving an appropriate amount of MC in the obtained solid, methanol was added to crystallize it. The crystallized solid was filtered and vacuum-dried to obtain a compound represented by Chemical Formula 1-2.

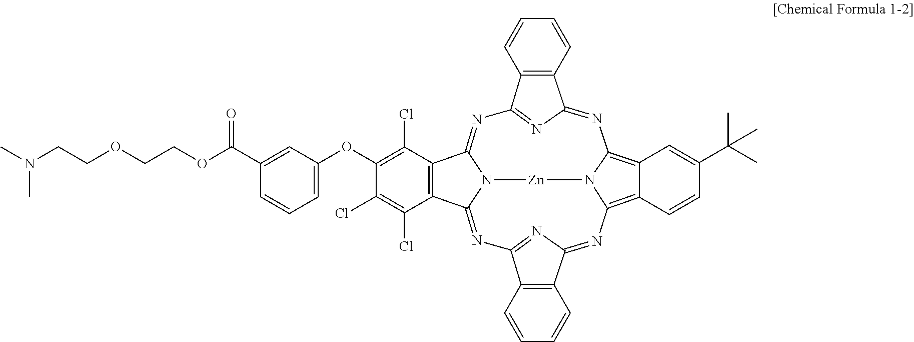

Maldi-tof MS: 986 m/z

### Synthesis Example 3: Compound Represented by Chemical Formula 1-3

### (1) Preparation of Intermediate 1-3-1

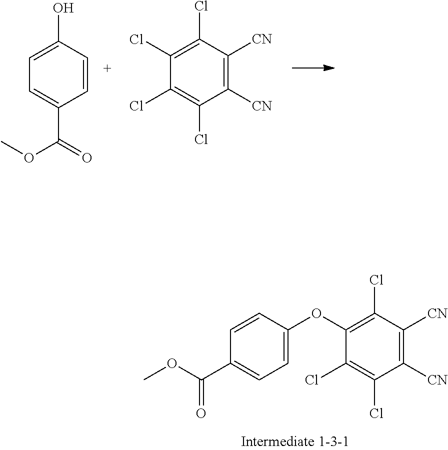 [SMILES: COC(=O)c1ccc(O)cc1 ; N#Cc1c(Cl)c(Cl)c(Cl)c(Cl)c1C#N ; COC(=O)c1ccc(Oc2c(Cl)c(Cl)c(C#N)c(C#N)c2Cl)cc1]

In a 250 ml flask, methyl 4-hydroxybenzoate (10 g), 3,4,5,6-tetrachlorophthalonitrile (17.5 g), K₂CO₃ (10.9 g), and N,N-dimethylformamide (DMF) (100 ml) were added and then stirred while heating to 70° C. After completion of the reaction, extraction was performed with EA (ethyl acetate). After extraction and concentration, it was purified by column chromatography. After purification and vacuum drying, Intermediate 1-3-1 was obtained.

### (2) Preparation of Intermediate 1-3-2

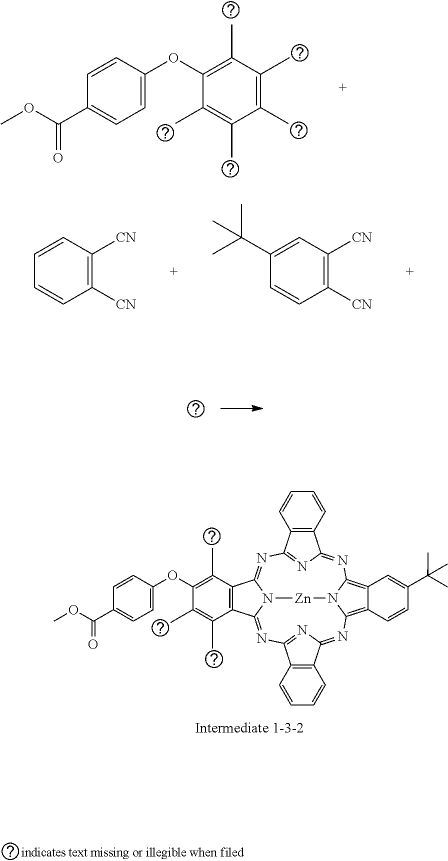

In a 100 mL flask, Intermediate 1-3-1 (4 g), phthalonitrile (1.34 g), 4-tert-butylphthalonitrile (1.93 g), 1,8-diazabicyclo[5.4.0]-7-undecene (3.19 g), and 1-pentenol (20 g) were added and then heated to 90° C., until the solids were dissolved, zinc acetate (1.93 g) was added thereto and then stirred while heating at 140° C. After the reaction was completed, the resultant was precipitated with methanol, filtered, and dried under vacuum. The dried solid was purified by column chromatography. After purification, an appropriate amount of MC was added to the obtained solid to dissolve the solid, and then methanol was added to crystallize it. The crystallized solid was filtered and vacuum-dried to obtain Intermediate 1-3-2.

### (3) Preparation of Compound Represented by Chemical Formula 1-3

In a 100 mL flask, Intermediate 1-3-2 (1.0 g), 2-[2-(dimethylamino)ethoxy]ethanol (0.30 g), and N,N-dimethylformamide (DMF) (10 ml) were added, and after connecting a condenser to the flask, a nitrogen atmosphere was formed. The resultant was stirred while heating to 100° C., and extracted with DIW and MC after the reaction was completed. The extracted organic layer was dehydrated with MgSO₄ and concentrated. After dissolving an appropriate amount of MC in the obtained solid, methanol was added to crystallize it. The crystallized solid was filtered and vacuum-dried to obtain a compound represented by Chemical Formula 1-3.

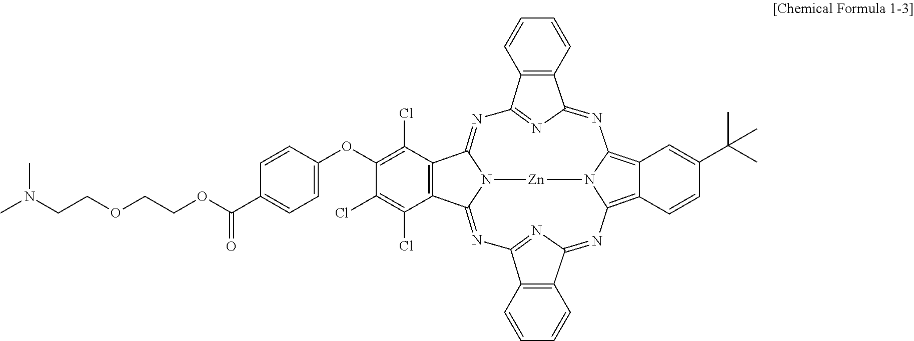

Maldi-tof MS: 986 m/z

### Synthesis Example 4: Compound Represented by Chemical Formula 1-4

### (1) Preparation of Intermediate 1-4-1

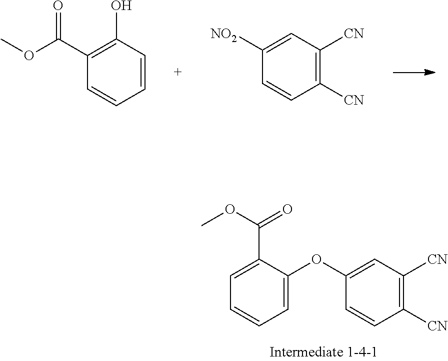 [SMILES: COC(=O)c1ccccc1O ; N#Cc1ccc([N+](=O)[O-])cc1C#N ; COC(=O)c1ccccc1Oc1ccc(C#N)c(C#N)c1]

In a 250 ml flask, methyl salicylate (10 g), 4-nitrophthalonitrile (11.4 g), K₂CO₃ (10.9 g), and N,N-dimethylformamide (DMF) (100 ml) were added and then stirred while heating at 70° C. After completion of the reaction, extraction was performed with EA (ethyl acetate). After extraction and concentration, it was purified by column chromatography. After purification and vacuum drying, Intermediate 1-4-1 was obtained.

### (2) Preparation of Intermediate 1-4-2

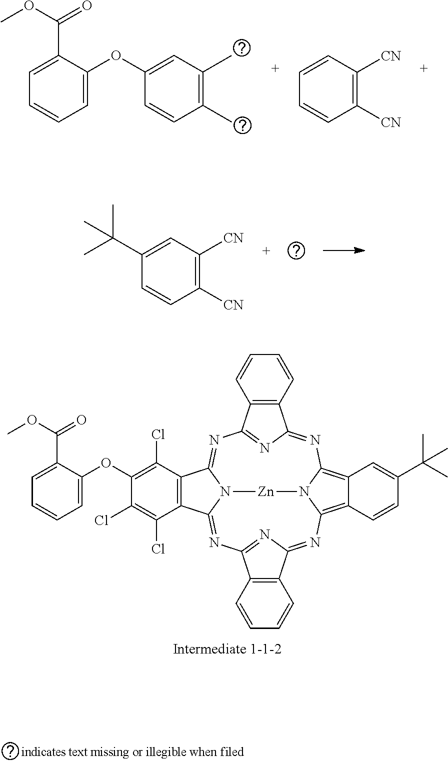

In a 100 mL flask, Intermediate 1-4-1 (4 g), phthalonitrile (3.68 g), 4-tert-butylphthalonitrile (2.65 g), 1,8-diazabicyclo[5.4.0]-7-undecene (3.19 g), and 1-pentenol (20 g) were added and then heated to 90° C., until the solids were dissolved, and zinc acetate (2.64 g) was added thereto and then stirred while heating at 140° C. After the reaction was completed, the resultant was precipitated with methanol, filtered, and dried under vacuum. The dried solid was purified by column chromatography. After purification, an appropriate amount of MC was added to the obtained solid to dissolve the solid, and then methanol was added to crystallize it. The crystallized solid was filtered and vacuum-dried to obtain Intermediate 1-4-2.

### (3) Preparation of Compound Represented by Chemical Formula 1-4

In a 100 mL flask, Intermediate 1-4-2 (1.0 g), 2-[2-(dimethylamino)ethoxy]ethanol (0.34 g), and N,N-dimethylformamide (DMF) (10 ml) were added, and after connecting a condenser to the flask, a nitrogen atmosphere was formed. The resultant was stirred while heating to 100° C., and extracted with DIW and MC after the reaction was completed. The extracted organic layer was dehydrated with MgSO₄ and concentrated. After dissolving an appropriate amount of MC in the obtained solid, methanol was added to crystallize it. The crystallized solid was filtered and vacuum-dried to obtain a compound represented by Chemical Formula 1-4.

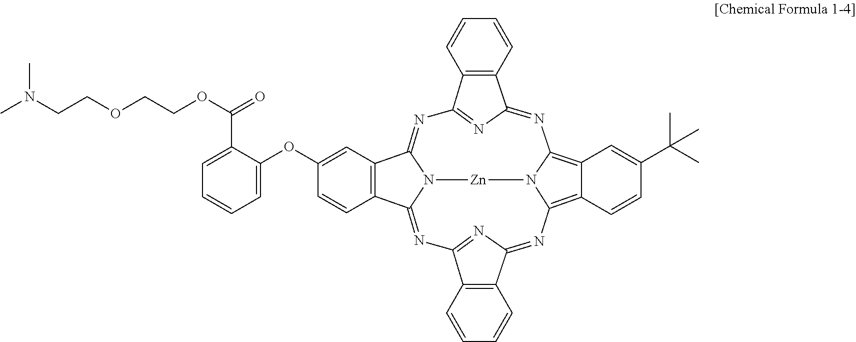

Maldi-tof MS: 884 m/z

### Synthesis Example 5: Compound Represented by Chemical Formula 1-5

### (1) Preparation of Intermediate 1-5-1

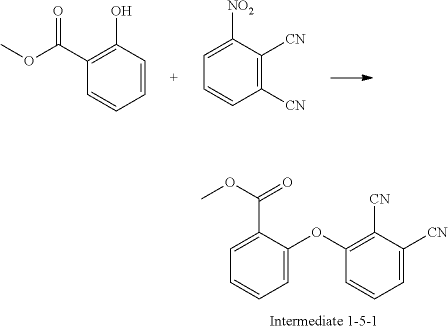 [SMILES: COC(=O)c1ccccc1O ; N#Cc1cccc([N+](=O)[O-])c1C#N ; COC(=O)c1ccccc1Oc1cccc(C#N)c1C#N]

In a 250 ml flask, methyl salicylate (10 g), 3-nitrophthalonitrile (11.4 g), K₂CO₃ (10.9 g), and N,N-dimethylformamide (DMF) (100 ml) were added and then stirred while heating at 70° C. After completion of the reaction, extraction was performed with EA (ethyl acetate). After extraction and concentration, it was purified by column chromatography. After purification and vacuum drying, Intermediate 1-5-1 was obtained.

### (2) Preparation of Intermediate 1-5-2

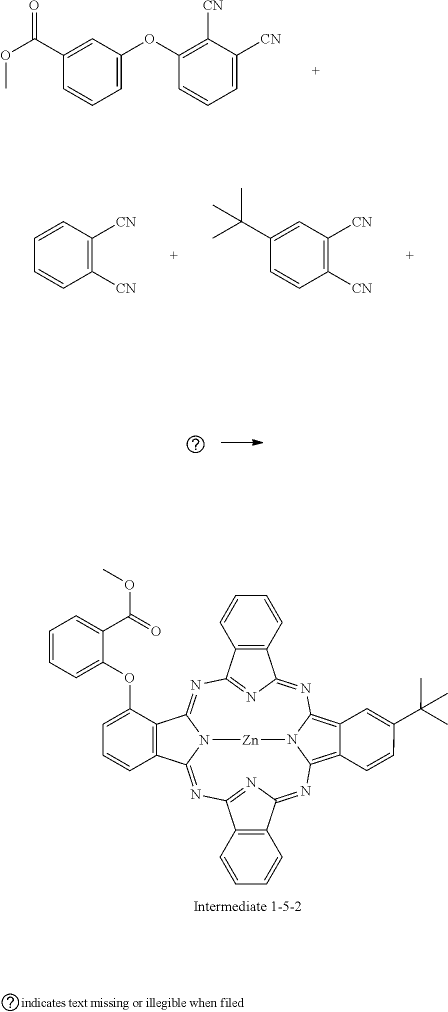

In a 100 mL flask, Intermediate 1-5-1 (4 g), phthalonitrile (3.68 g), 4-tert-butylphthalonitrile (2.65 g), 1,8-diazabicyclo[5.4.0]-7-undecene (3.19 g), and 1-pentenol (20 g) were added and then heated to 90° C., until the solids were dissolved, and zinc acetate (2.64 g) was added thereto and then stirred while heating at 140° C. After the reaction was completed, the resultant was precipitated with methanol, filtered, and dried under vacuum. The dried solid was purified by column chromatography. After purification, an appropriate amount of MC was added to the obtained solid to dissolve the solid, and then methanol was added to crystallize it. The crystallized solid was filtered and vacuum-dried to obtain Intermediate 1-5-2.

### (3) Preparation of Compound Represented by Chemical Formula 1-5

In a 100 mL flask, Intermediate 1-5-2 (1.0 g), 2-[2-(dimethylamino)ethoxy]ethanol (0.34 g), and N,N-dimethylformamide (DMF) (10 ml) were added, and after connecting a condenser to the flask, a nitrogen atmosphere was formed. The resultant was stirred while heating to 100° C., and extracted with DIW and MC after the reaction was completed. The extracted organic layer was dehydrated with MgSO₄ and concentrated. After dissolving an appropriate amount of MC in the obtained solid, methanol was added to crystallize it. The crystallized solid was filtered and vacuum-dried to obtain a compound represented by Chemical Formula 1-5.

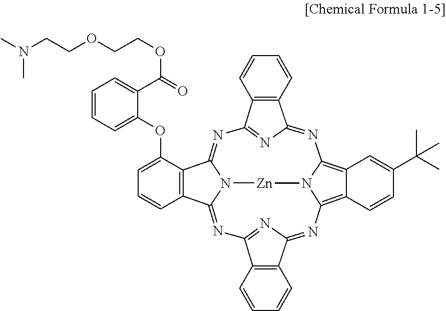

Maldi-tof MS: 884 m/z

### Synthesis Example 6: Compound Represented by Chemical Formula 1-6

In a 100 mL flask, Intermediate 1-5-2 (1.0 g), 2-[2-(diethylamino)ethoxy]ethanol (0.41 g), and N,N-dimethylformamide (DMF) (10 ml) were added, and after connecting a condenser to the flask, a nitrogen atmosphere was formed. The resultant was stirred while heating to 100° C., and extracted with DIW and MC after the reaction was completed. The extracted organic layer was dehydrated with MgSO₄ and concentrated. After dissolving an appropriate amount of MC in the obtained solid, methanol was added to crystallize it. The crystallized solid was filtered and vacuum-dried to obtain a compound represented by 1-6.

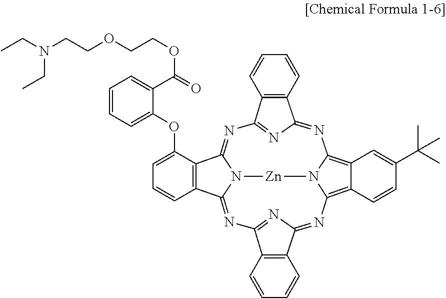

Maldi-tof MS: 912 m/z

### Synthesis Example 7: Compound Represented by Chemical Formula 1-7

### (1) Preparation of Intermediate 1-7-1

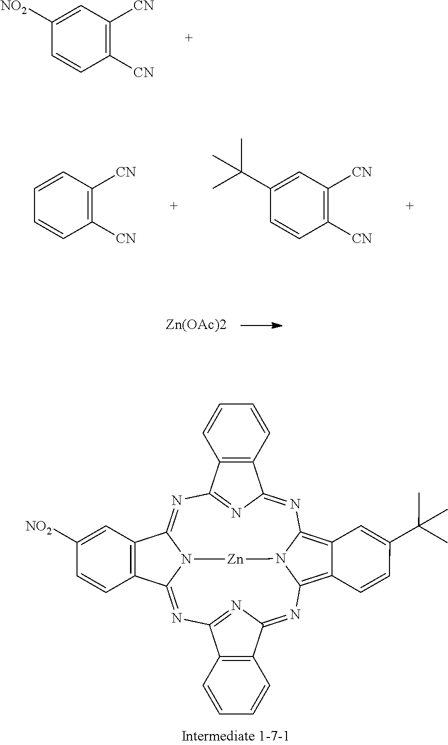

In a 250 ml flask, 4-nitro-phthalonitrile (10.0 g), phthalonitrile (14.80 g), 4-tert-Butylphthalonitrile (10.64 g), 1,8-diazabicyclo[5.4.0]-7-undecene (8.79 g), and 1-pentenol (100 g) were added and then heated to 90° C., until the solids were dissolved, and zine acetate (10.60 g) was added thereto and then stirred while heating at 140° C. After the reaction was completed, methanol was added to confirm precipitation, followed by filtering, and vacuum-drying. The dried solid was purified by column chromatography. After purification, an appropriate amount of MC was added to the obtained solid to dissolve the solid, and then methanol as added to crystallize it. The crystallized solid was filtered and vacuum-dried to obtain Intermediate 1-7-1.

### (2) Preparation of Compound Represented by Chemical Formula 1-7

In a 100 mL flask, Intermediate 1-7-1 (5.0 g), 2-[2-(dimethylamino)ethoxy]ethanol (1.96 g), K₂CO₃ (3.05 g), and N,N-dimethylformamide (DMF) (50 ml) were added and then stirred while heating to 70° C. After the reaction was completed, the resultant was poured into methanol to confirm precipitation, and then filtered, vacuum-dried, and purified using column chromatography. After purification, the solid was vacuum-dried, an appropriate amount of MC was added to the dried solid, the solid was dissolved, and then methanol was added to crystallize it. The crystallized solid was filtered and vacuum-dried to obtain a compound represented by Chemical Formula 1-7.

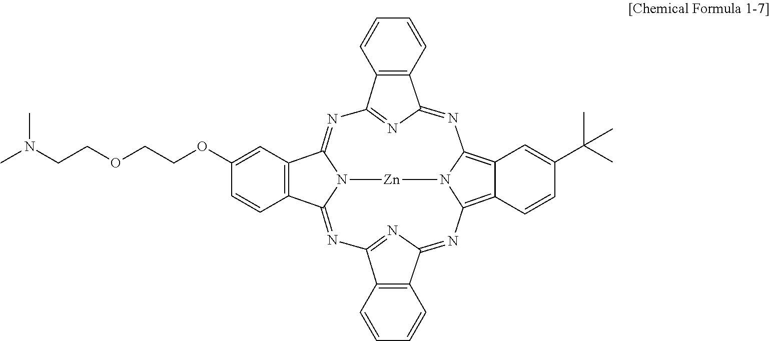

Maldi-tof MS: 764 m/z

### Synthesis Example 8: Compound Represented by Chemical Formula 1-8

### (1) Preparation of Compound Represented by Chemical Formula 1-8

In a 100 mL flask, Intermediate 1-7-1 (5.0 g), 2-[2-(diethylamino)ethoxy]ethanol (2.37 g), K₂CO₃ (3.05 g), and N,N-dimethylformamide (DMF) (50 ml) were added and then stirred while heating to 70° C. After the reaction was completed, the resultant was poured into methanol to confirm precipitation, and then filtered, vacuum-dried, and purified using column chromatography. After purification, the solid was vacuum-dried, an appropriate amount of MC was added to the dried solid, the solid was dissolved, and then methanol was added to crystallize it. The crystallized solid was filtered and vacuum-dried to obtain a compound represented by Chemical Formula 1-8.

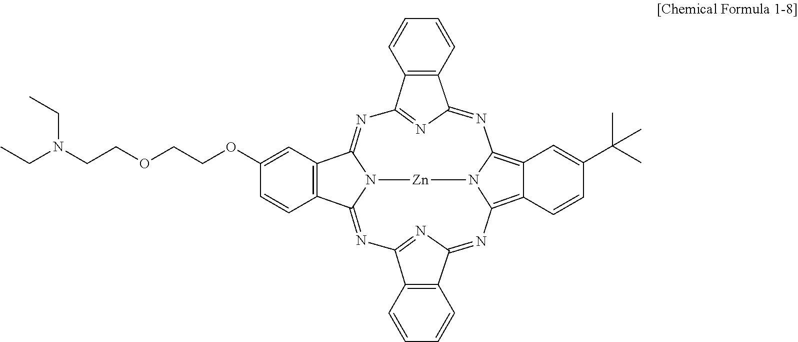

Maldi-tof MS: 792 m/z

### Synthesis Example 9: Compound Represented by Chemical Formula 1-9

### (1) Preparation of Compound Represented by Chemical Formula 1-9

In a 100 mL flask, Intermediate 1-7-1 (5.0 g), 2-[2-[2-(dimethylamino)ethoxy]ethoxy]ethanol (2.61 g), K₂CO₃ (3.05 g), and N,N-dimethylformamide (DMF) (50 ml) were added and then stirred while heating to 70° C. After the reaction was completed, the resultant was poured into methanol to confirm precipitation, and then filtered, vacuum-dried, and purified using column chromatography. After purification, the solid was vacuum-dried, an appropriate amount of MC was added to the dried solid, the solid was dissolved, and then methanol was added to crystallize it. The crystallized solid was filtered and vacuum-dried to obtain a compound represented by Chemical Formula 1-9.

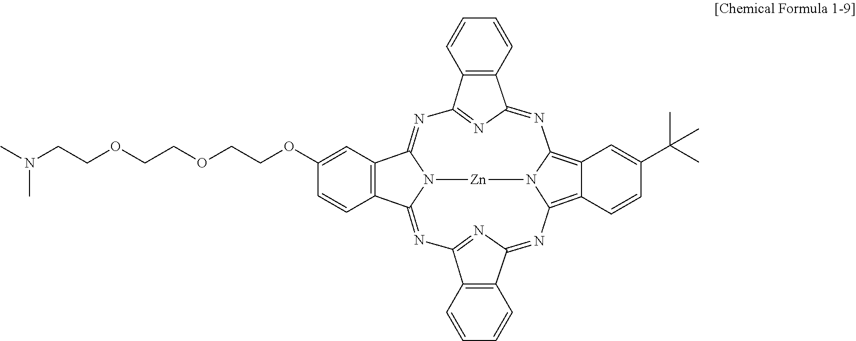

Maldi-tof MS: 808 m/z

### Synthesis Example 10: Compound Represented by Chemical Formula 1-10

### (1) Preparation of Intermediate 1-10-1

In a 100 mL flask, Intermediate 1-7-1 (5.0 g), 2-[2-[2-(diethylamino)ethoxy]ethoxy]ethanol (3.02 g), K₂CO₃ (3.05 g), and N,N-dimethylformamide (DMF) (50 ml) were added and then stirred while heating to 70° C. After the reaction was completed, the resultant was poured into methanol to confirm precipitation, and then filtered, vacuum-dried, and purified using column chromatography. After purification, the solid was vacuum-dried, an appropriate amount of MC was added to the dried solid, the solid was dissolved, and then methanol was added to crystallize it. The crystallized solid was filtered and vacuum-dried to obtain a compound represented by Chemical Formula 1-10.

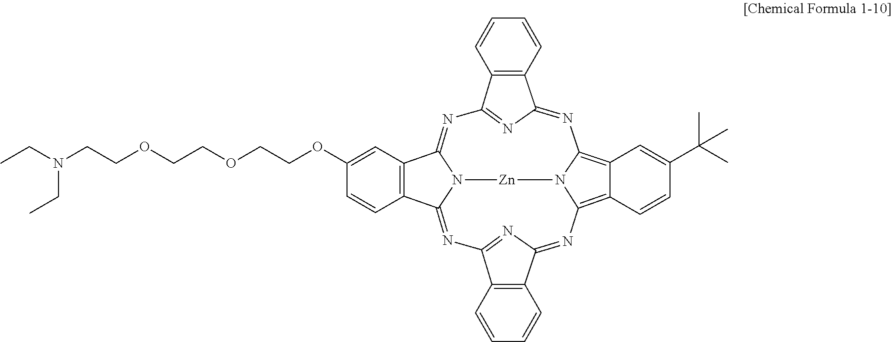

Maldi-tof MS: 836 m/z

### Synthesis Example 11: Compound Represented by Chemical Formula 1-11

### (1) Preparation of Intermediate 1-11-1

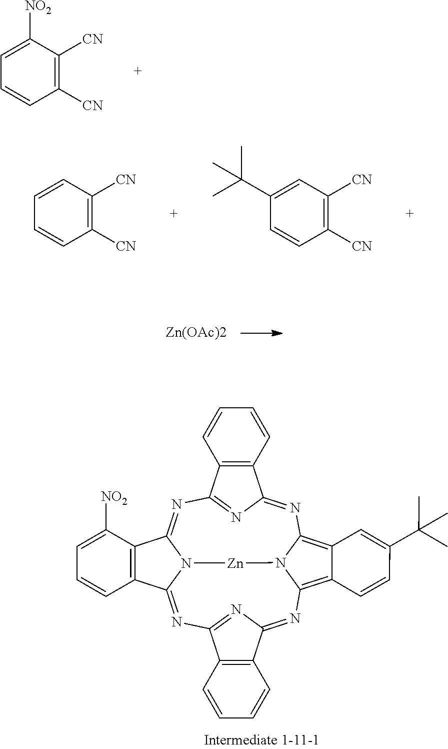

In a 250 ml flask, 3-nitro-phthalonitrile (10.0 g), phthalonitrile (14.80 g), 4-tert-butylphthalonitrile (10.64 g), 1,8-Diazabicyclo[5.4.0]-7-undecene (8.79 g), and 1-pentenol (100 g) were added and then heated to 90° C., until the solids were dissolved, and zine acetate (10.60 g) was added thereto and then stirred while heating at 140° C. After the reaction was completed, methanol was added to confirm precipitation, followed by filtering, and vacuum-drying. The dried solid was purified by column chromatography. After purification, an appropriate amount of MC was added to the obtained solid to dissolve the solid, and then methanol was added to crystallize it. The crystallized solid was filtered and vacuum-dried to obtain Intermediate 1-11-1.

### (2) Preparation of Compound Represented by Chemical Formula 1-11

In a 100 mL flask, Intermediate 1-11-1 (5.0 g), 2-[2-(dimethylamino)ethoxy]ethanol (1.96 g), K₂CO₃ (3.05 g), and N,N-dimethylformamide (DMF) (50 ml) were added and then stirred while heating to 70° C. After the reaction was completed, the resultant was poured into methanol to confirm precipitation, and then filtered, vacuum-dried, and purified using column chromatography. After purification, the solid was vacuum-dried, an appropriate amount of MC was added to the dried solid, the solid was dissolved, and then methanol was added to crystallize it. The crystallized solid was filtered and vacuum-dried to obtain a compound represented by Chemical Formula 1-11.

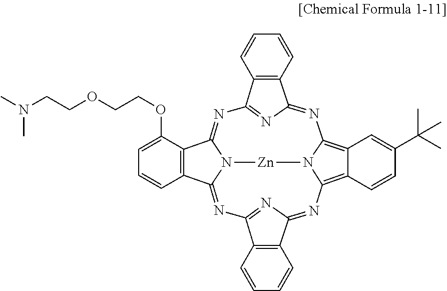

Maldi-tof MS: 764 m/z

### Synthesis Example 12: Compound Represented by Chemical Formula 1-12

### (1) Preparation of Intermediate 1-12-1

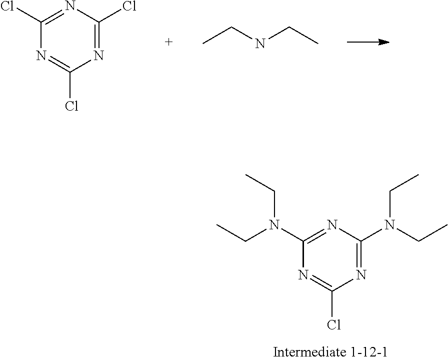

In a 250 ml flask, cyanuric chloride (10 g) was dissolved in THE (100 ml) and then cooled in an ice bath. Diethylamine (8.13 g) and triethylamine (24.1 g) were slowly added to the solution for 1 hour. When the addition was completed, the mixture was reacted at ambient temperature for 1 day and then filtered to remove solid components. The filtered solution was concentrated with a reduced pressure evaporator and then purified through column chromatography. After purification and vacuum drying, Intermediate 1-12-1 was obtained.

### (2) Preparation of Intermediate 1-12-2

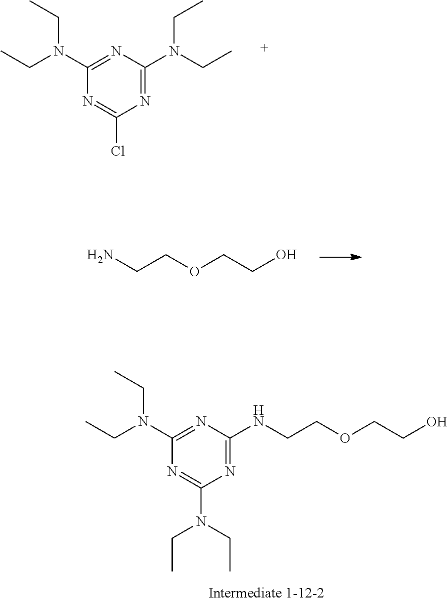 [SMILES: CCN(CC)c1nc(Cl)nc(N(CC)CC)n1 ; NCCOCCO ; CCN(CC)c1nc(NCCOCCO)nc(N(CC)CC)n1]

In a 250 ml flask, Intermediate 1-12-1 (10 g) was dissolved in acetone (100 ml) and then cooled in an ice bath. 2-(2-aminoethoxy)ethanol (4.89 g) was slowly added to the solution, and a solution prepared by dissolving sodium bicarbonate (6.60 g) in distilled water (60 ml) was slowly added thereto. When the addition was completed, the mixture was reacted under reflux for one day, concentrated with a reduced pressure evaporator, and extracted with EA (ethyl acetate). After extraction and concentration, it was purified by column chromatography. After purification and vacuum drying, Intermediate 1-12-2 was obtained.

### (3) Preparation of Compound Represented by Chemical Formula 1-12

In a 100 mL flask, Intermediate 1-7-1 (5.0 g), Intermediate 1-12-2 (4.81 g), K₂CO₃ (3.05 g), and N,N-dimethylformamide (DMF) (50 ml) were added and then stirred while heating to 70° C. After the reaction was completed, the resultant was poured into methanol to confirm precipitation, and then filtered, vacuum-dried, and purified using column chromatography. After purification, the solid was vacuum-dried, an appropriate amount of MC was added to the dried solid, the solid was dissolved, and then methanol was added to crystallize it. The crystallized solid was filtered and vacuum-dried to obtain a compound represented by Chemical Formula 1-12.

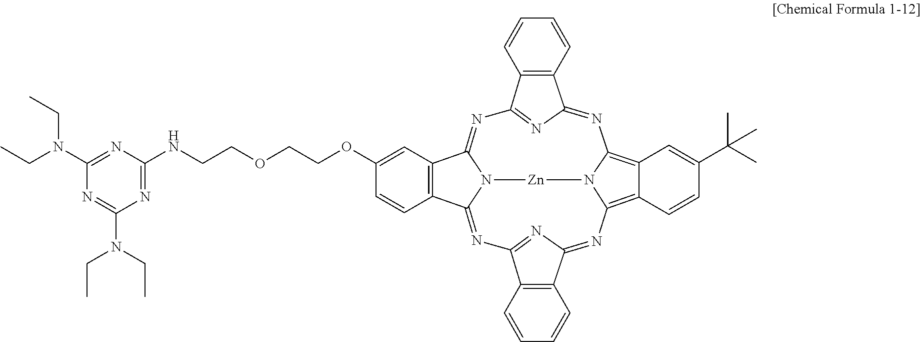

Maldi-tof MS: 957 m/z

### Synthesis Example 13: Compound Represented by Chemical Formula 1-13

In a 100 mL flask, Intermediate 1-11-1 (5.0 g), Intermediate 1-12-2 (4.81 g), K₂CO₃ (3.05 g), and N,N-dimethylformamide (DMF) (50 ml) were added and then stirred while heating to 70° C. After the reaction was completed, the resultant was poured into methanol to confirm precipitation, and then filtered, vacuum-dried, and purified using column chromatography. After purification, the solid was vacuum-dried, an appropriate amount of MC was added to the dried solid, the solid was dissolved, and then methanol was added to crystallize it. The crystallized solid was filtered and vacuum-dried to obtain a compound represented by Chemical Formula 1-13.

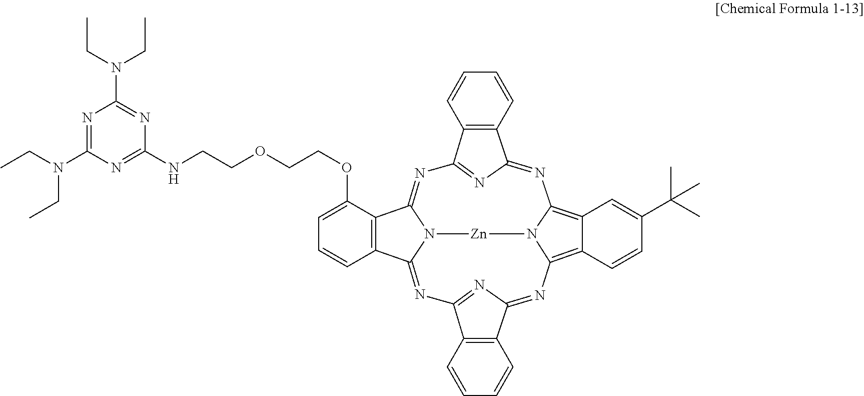

Maldi-tof MS: 957 m/z

### Comparative Synthesis Example 1

### (1) Preparation of Intermediate C-1

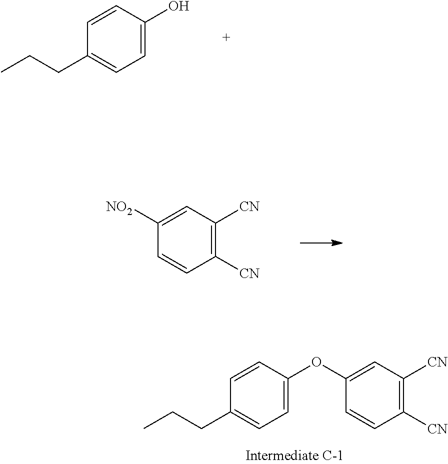

In a 100 ml flask, 4-propylphenol (5 g), 4-nitrophthalonitrile (6.35 g), K2CO3 (6.08 g), and N,N-dimethylformamide (DMF) (25 ml) were added and then stirred while heating to 70° C. After completion of the reaction, extraction was performed with EA (ethyl acetate). After extraction and concentration, it was purified by column chromatography. After purification and vacuum drying, Intermediate C-1 was obtained.

### (3) Preparation of Compound Represented by Chemical Formula C

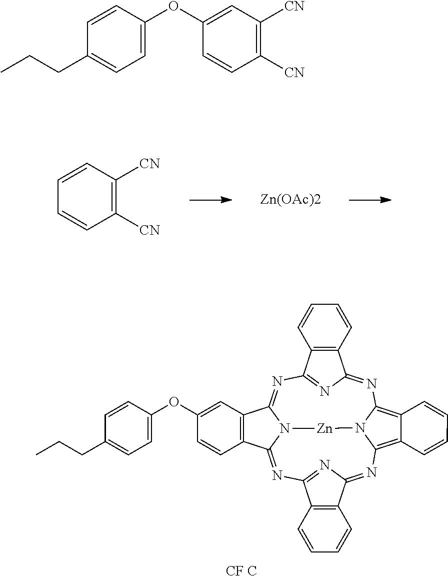

In a 100 mL flask, Intermediate C-1 (3 g), phthalonitrile (4.40 g), 1,8-diazabicycloundec-7-ene (2.08 g), and 1-pentenol (30 g) were added and then heated to 90° C., until the solids were dissolved, and zinc acetate (2.10 g) was added thereto and then stirred while heating at 140° C. After the reaction was completed, the resultant was precipitated with methanol, filtered, and dried under vacuum. The dried solid was purified by column chromatography. After purification, an appropriate amount of MC was added to the obtained solid to dissolve the solid, and then methanol was added to crystallize it. The crystallized solid was filtered and vacuum-dried to obtain a compound represented by Chemical Formula S-1.

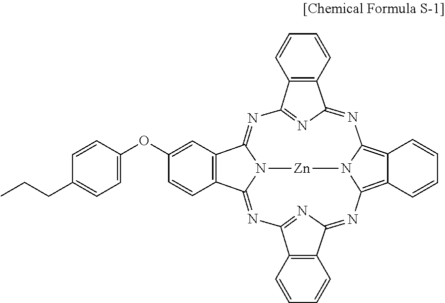

Maldi-tof MS: 711 m/z

### Comparative Synthesis Example 2

### (1) Preparation of Compound Represented by Chemical Formula C-2

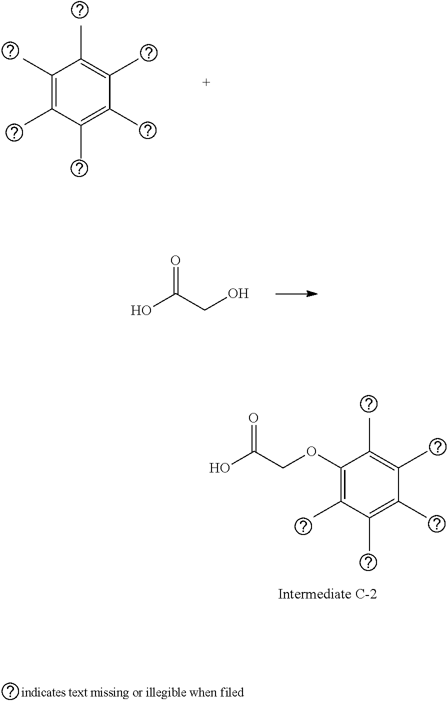

In a 100 ml flask, glycolic acid (2.38 g), 3,4,5,6-tetrachlorophthalonitrile (5 g), K₂CO₃ (3.46 g), and N,N-dimethylformamide (DMF) (27 ml) were added and then stirred while heating to 70° C. When a reaction was completed, the reaction solution was cooled to ambient temperature and filtered under a reduced pressure to remove inorganic salts. The obtained filtrate was concentrated and purified through column chromatography. After purification and vacuum drying, Intermediate C-2 was obtained.

### (2) Preparation of Compound Represented by Chemical Formula S-2

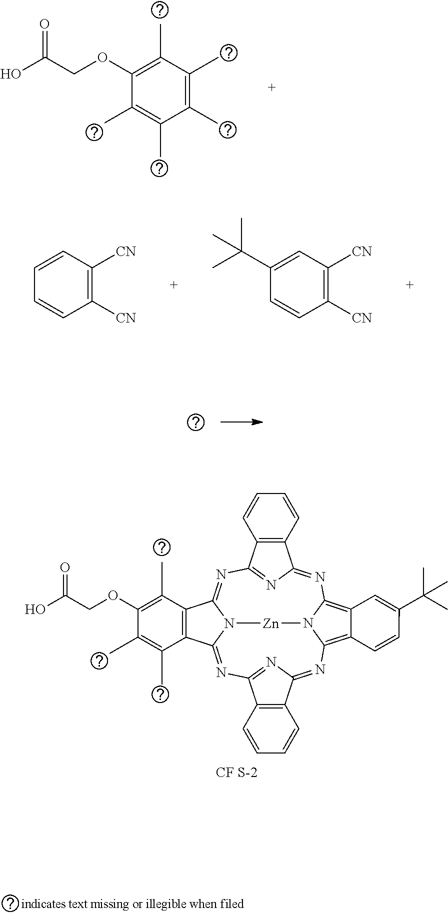

In a 250 mL flask, Intermediate C-2 (10.0 g), phthalonitrile (8.39 g), 4-tert-butylphthalonitrile (6.03 g), 1,8-diazabicyclo[5.4.0]-7-undecene (12.46 g), and 1-pentenol (85.47 g) were added and then heated to 90° C., until the solids were dissolved, and zinc acetate (6.01 g) was added thereto and then stirred while heating at 140° C. After the reaction was completed, methanol was added to confirm precipitation, followed by filtering, and vacuum-drying. The dried solid was purified by column chromatography. After purification, an appropriate amount of MC was added to the obtained solid to dissolve the solid, and then methanol was added to crystallize it. The crystallized solid was filtered and vacuum dried to obtain a compound represented by Chemical Formula S-2.

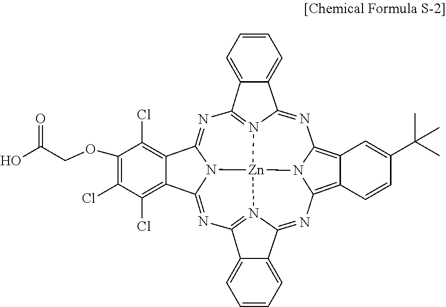

Maldi-tof MS: 808 m/z

### Comparative Synthesis Example 3

### (1) Preparation of Compound Represented by Chemical Formula C-3

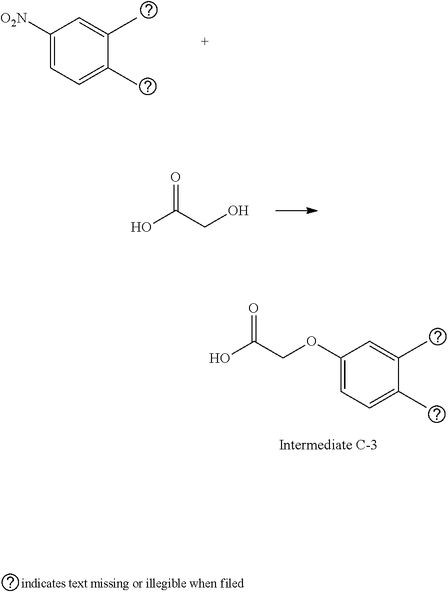

In a 100 ml flask, glycolic acid (2.86 g), 4-nitrophthalonitrile (5 g), K₂CO₃ (5.99 g), and N,N-dimethylformamide (DMF) (27 ml) were added and then stirred while heating the 70° C. When a reaction was completed, the reaction solution was cooled to ambient temperature and filtered under a reduced pressure to remove inorganic salts. The obtained filtrate was concentrated and purified through column chromatography. After purification and vacuum drying, Intermediate C-3 was obtained.

### (2) Preparation of Compound Represented by Chemical Formula S-3

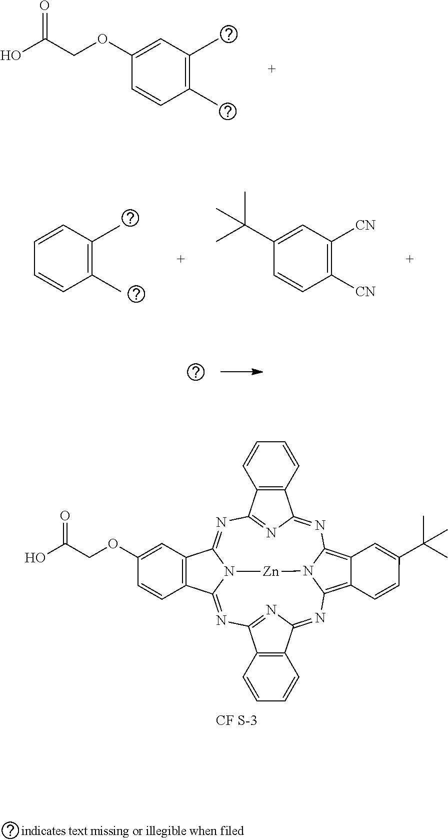

In a 250 mL flask, Intermediate C-3 (10.0 g), phthalonitrile (12.68 g), 4-tert-butylphthalonitrile (9.11 g), 1,8-diazabicyclo[5.4.0]-7-undecene (18.83 g), and 1-pentenol (111.26 g) were added and then heated to 90° C., until the solids were dissolved, and zinc acetate (9.08 g) was added thereto and then stirred while heating at 140° C. After the reaction was completed, methanol was added to confirm precipitation, followed by filtering, and vacuum-drying. The dried solid was purified by column chromatography. After purification, an appropriate amount of MC was added to the obtained solid to dissolve the solid, and then methanol was added to crystallize it. The crystallized solid was filtered and vacuum dried to obtain a compound represented by Chemical Formula S-3.

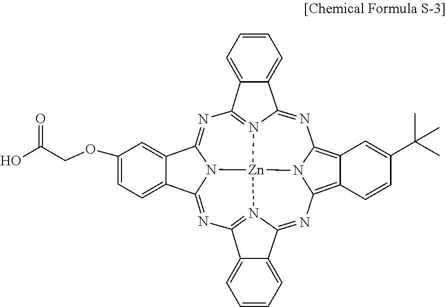

Maldi-tof MS: 706 m/z

### Preparation of Green Pigment Dispersion

Green pigment dispersions of Preparation Examples 1 to 14 and Comparative Preparation Examples 1 to 6 were prepared by mixing to have compositions shown in Table 1 (unit: wt %) and Table 2 (unit: wt %).

Specifically, a green pigment, a dispersant, a dispersion aid, a dispersion binder, and a solvent were mixed, based on 100 parts by weight of the mixture, 300 parts by weight zirconia beads (a diameter: 0.4 μm) were added to disperse the mixture with a paint shaker for 3 hours, and the zirconia beads were removed by filtration. Subsequently, the zirconia beads (a diameter: 0.2 μm) were added again thereto to additionally perform the dispersion with the paint shaker for 3 hours, and a green pigment dispersion was obtained by removing the zirconia beads by filtration with a 0.45 μm PP syringe filter.

TABLE 1

| | | Prep. | Prep. | Prep. | Prep. | Prep. | Prep. | Prep. | Prep. | Prep. | Prep. |
|---|---|---|---|---|---|---|---|---|---|---|---|
| | | Ex. 1 | Ex. 2 | Ex. 3 | Ex. 4 | Ex. 5 | Ex. 6 | Ex. 7 | Ex. 8 | Ex. 9 | Ex. 10 |
| Green pigment | | 63.6 | 63.6 | 63.6 | 63.6 | 63.6 | 63.6 | 63.6 | 63.6 | 63.6 | 63.6 |
| Dispersant | | 19.1 | 14.5 | 14.5 | 14.5 | 14.5 | 14.5 | 14.5 | 14.5 | 14.5 | 14.5 |
| Dispersion binder | | 8.7 | 8.7 | 8.7 | 8.7 | 8.7 | 8.7 | 8.7 | 8.7 | 8.7 | 8.7 |
| Dispersion | Syn. Ex. 1 | 8.6 | 13.2 | — | — | — | — | — | — | — | — |
| aid | Syn. Ex. 2 | — | — | 13.2 | — | — | — | — | — | — | — |
| | Syn. Ex. 3 | — | — | — | 13.2 | — | — | — | — | — | — |
| | Syn. Ex. 4 | — | — | — | — | 13.2 | — | — | — | — | — |
| | Syn. Ex. 5 | — | — | — | — | — | 13.2 | — | — | — | — |
| | Syn. Ex. 6 | — | — | — | — | — | — | 13.2 | — | — | — |
| | Syn. Ex. 7 | — | — | — | — | — | — | — | 13.2 | — | — |
| | Syn. Ex. 8 | — | — | — | — | — | — | — | — | 13.2 | — |
| | Syn. Ex. 9 | — | — | — | — | — | — | — | — | — | 13.2 |

| | | | | | | | | | | |
|---|---|---|---|---|---|---|---|---|---|---|
| Total solid content | 100 | 100 | 100 | 100 | 100 | 100 | 100 | 100 | 100 | 100 |
| Solvent | 400 | 400 | 400 | 400 | 400 | 400 | 400 | 400 | 400 | 400 |
| Amount of dispersion | 8.6 | 13.2 | 13.2 | 13.2 | 13.2 | 13.2 | 13.2 | 13.2 | 13.2 | 13.2 |
| aid in solid content | | | | | | | | | | |

TABLE 2

| | | | | | | Comp. | Comp. | Comp. | Comp. | Comp. | Comp. |
|---|---|---|---|---|---|---|---|---|---|---|---|
| | | Prep. | Prep. | Prep. | Prep. | Prep. | Prep. | Prep. | Prep. | Prep. | Prep. |
| | | Ex. 11 | Ex. 12 | Ex. 13 | Ex. 14 | Ex. 1 | Ex. 2 | Ex. 3 | Ex. 4 | Ex. 5 | Ex. 6 |
| Green pigment | | 63.6 | 63.6 | 63.6 | 63.6 | 63.6 | 63.6 | 63.6 | 63.6 | 63.6 | 63.6 |
| Dispersant | | 14.5 | 14.5 | 14.5 | 14.5 | 27.7 | 14.5 | 19.1 | 19.1 | 14.5 | 14.5 |
| Dispersion binder | | 8.7 | 8.7 | 8.7 | 8.7 | 8.7 | 8.7 | 12.8 | 8.7 | 8.7 | 8.7 |
| Dispersion | Syn. Ex. 10 | 13.2 | — | — | — | — | — | — | — | — | — |
| aid | Syn. Ex. 11 | — | 13.2 | — | — | — | — | — | — | — | — |
| | Syn. Ex. 12 | — | — | 13.2 | — | — | — | — | — | — | — |
| | Syn. Ex. 13 | — | — | — | 13.2 | — | — | — | — | — | — |
| | Comp. Syn. | — | — | — | — | — | 13.2 | — | — | — | — |
| | Ex. 1 | | | | | | | | | | |
| | Comp. Syn. | — | — | — | — | — | — | 4.5 | 8.6 | 13.2 | — |
| | Ex. 2 | | | | | | | | | | |
| | Comp. Syn. | — | — | — | — | — | — | — | — | — | 13.2 |
| | Ex. 3 | | | | | | | | | | |

| | | | | | | | | | | |
|---|---|---|---|---|---|---|---|---|---|---|
| Total solid content | 100 | 100 | 100 | 100 | 100 | 100 | 100 | 100 | 100 | 100 |
| Solvent | 400 | 400 | 400 | 400 | 400 | 400 | 400 | 400 | 400 | 400 |
| Amount of dispersion | 13.2 | 13.2 | 13.2 | 13.2 | 0 | 13.2 | 4.5 | 8.6 | 13.2 | 13.2 |
| aid in solid content | | | | | | | | | | |

The materials used in Tables 1 and 2 are as follows.
Green pigment: C.I. PIGMENT Green 58 (Manufacturer: DIC Co., Ltd.)
Dispersant: Disperbyk LPN 6919 (Manufacturer: BYK-Chemie)
Dispersion binder: SP-RY-99 (Manufacturer: Showadenko)
Dispersion aid: Each compound of Synthesis Example 1 to 13 and Comparative Synthesis Example 1 to 3
Solvent: propylene glycol monomethylether acetate (PGMEA) (Manufacturer: Daicel)

### Preparation of Yellow Pigment Dispersion

A yellow pigment dispersion was obtained in the same manner as in the green pigment dispersion-manufacturing method except that a yellow pigment (C.I. PIGMENT Yellow 185, SANYO Chemical Co., Ltd.) was used instead of the green pigment.

### Preparation of Photosensitive Resin Composition

Photosensitive resin compositions of Examples 1 to 14 and Comparative Examples 1 to 6 were manufactured by mixing to have compositions shown in Table 3 (unit: wt %) and Table 4 (unit: wt %).

Specifically, a green pigment dispersion, a yellow pigment dispersion, a photopolymerizable monomer, a photopolymerization initiator, a binder resin, and a solvent were mixed to prepare the photosensitive coloring resin compositions.

TABLE 3

| | | | Ex. 1 | Ex. 2 | Ex. 3 | Ex. 4 | Ex. 5 | Ex. 6 | Ex. 7 | Ex. 8 | Ex. 9 | Ex. 10 |
|---|---|---|---|---|---|---|---|---|---|---|---|---|
| (A) | Green | Prep. | 49 | — | — | — | — | — | — | — | — | — |
| Colorant | pigment | Ex. 1 | | | | | | | | | | |
| | dispersion | Prep. | — | 49 | — | — | — | — | — | — | — | — |
| | | Ex. 2 | | | | | | | | | | |
| | | Prep. | — | — | 49 | — | — | — | — | — | — | — |
| | | Ex. 3 | | | | | | | | | | |
| | | Prep. | — | — | — | 49 | — | — | — | — | — | — |
| | | Ex. 4 | | | | | | | | | | |
| | | Prep. | — | — | — | — | 49 | — | — | — | — | — |
| | | Ex. 5 | | | | | | | | | | |
| | | Prep. | — | — | — | — | — | 49 | — | — | — | — |
| | | Ex. 6 | | | | | | | | | | |
| | | Prep. | — | — | — | — | — | — | 49 | — | — | — |
| | | Ex. 7 | | | | | | | | | | |
| | | Prep. | — | — | — | — | — | — | — | 49 | — | — |
| | | Ex. 8 | | | | | | | | | | |
| | | Prep. | — | — | — | — | — | — | — | — | 49 | — |
| | | Ex. 9 | | | | | | | | | | |
| | | Prep. | — | — | — | — | — | — | — | — | — | 49 |
| | | Ex. 10 | | | | | | | | | | |

| | | | | | | | | | | |
|---|---|---|---|---|---|---|---|---|---|---|
| Yellow pigment | 35 | 35 | 35 | 35 | 35 | 35 | 35 | 35 | 35 | 35 |
| dispersion | | | | | | | | | | |

| | | | | | | | | | | |
|---|---|---|---|---|---|---|---|---|---|---|
| (B) Photopolymerization | 10 | 10 | 10 | 10 | 10 | 10 | 10 | 10 | 10 | 10 |
| monomer | | | | | | | | | | |
| (C) Photopolymerization | 2.08 | 2.08 | 2.08 | 2.08 | 2.08 | 2.08 | 2.08 | 2.08 | 2.08 | 2.08 |
| initiator | | | | | | | | | | |
| (D) Binder resin | 3.7 | 3.7 | 3.7 | 3.7 | 3.7 | 3.7 | 3.7 | 3.7 | 3.7 | 3.7 |
| Antioxidant | 0.2 | 0.2 | 0.2 | 0.2 | 0.2 | 0.2 | 0.2 | 0.2 | 0.2 | 0.2 |
| Additives | 0.02 | 0.02 | 0.02 | 0.02 | 0.02 | 0.02 | 0.02 | 0.02 | 0.02 | 0.02 |
| Total solid content | 100 | 100 | 100 | 100 | 100 | 100 | 100 | 100 | 100 | 100 |
| (E) Solvent | 500 | 500 | 500 | 500 | 500 | 500 | 500 | 500 | 500 | 500 |
| Amount of dispersion aid | 4.21 | 6.47 | 6.47 | 6.47 | 6.47 | 6.47 | 6.47 | 6.47 | 6.47 | 6.47 |
| in solid content (%) | | | | | | | | | | |

TABLE 4

| | | | Ex | Ex. | Ex. | Ex | Comp. | Comp. | Comp. | Comp. | Comp. | Comp. |
|---|---|---|---|---|---|---|---|---|---|---|---|---|
| | | | 11 | 12 | 13 | 14 | Ex. 1 | Ex. 2 | Ex. 3 | Ex. 4 | Ex. 5 | Ex. 6 |
| (A) | Green | Prep. Ex. 11 | 49 | — | — | — | — | — | — | — | — | — |
| Colorant | pigment | Prep. Ex. 12 | — | 49 | — | — | — | — | — | — | — | — |
| | dispersion | Prep. Ex. 13 | — | — | 49 | — | — | — | — | — | — | — |
| | | Prep. Ex. 14 | — | — | — | 49 | — | — | — | — | — | — |
| | | Comp. Syn. | — | — | — | — | 49 | — | — | — | — | — |
| | | Ex. 1 | | | | | | | | | | |
| | | Comp. Syn. | — | — | — | — | — | 49 | — | — | — | — |
| | | Ex. 2 | | | | | | | | | | |
| | | Comp. Syn. | — | — | — | — | — | — | 49 | — | — | — |
| | | Ex. 3 | | | | | | | | | | |
| | | Comp. Syn. | — | — | — | — | — | — | — | 49 | — | — |
| | | Ex. 4 | | | | | | | | | | |
| | | Comp. Syn. | — | — | — | — | — | — | — | — | 49 | — |
| | | Ex. 5 | | | | | | | | | | |
| | | Comp. Syn. | — | — | — | — | — | — | — | — | — | 49 |
| | | Ex. 6 | | | | | | | | | | |

| | | | | | | | | | | |
|---|---|---|---|---|---|---|---|---|---|---|
| Yellow pigment | 35 | 35 | 35 | 35 | 35 | 35 | 35 | 35 | 35 | 35 |
| dispersion | | | | | | | | | | |

| | | | | | | | | | | |
|---|---|---|---|---|---|---|---|---|---|---|
| (B) Photopolymerization | 10 | 10 | 10 | 10 | 10 | 10 | 10 | 10 | 10 | 10 |
| monomer | | | | | | | | | | |
| (C) Photopolymerization | 2.08 | 2.08 | 2.08 | 2.08 | 2.08 | 2.08 | 2.08 | 2.08 | 2.08 | 2.08 |
| initiator | | | | | | | | | | |
| (D) Binder resin | 3.7 | 3.7 | 3.7 | 3.7 | 3.7 | 3.7 | 3.7 | 3.7 | 3.7 | 3.7 |
| Antioxidant | 0.2 | 0.2 | 0.2 | 0.2 | 0.2 | 0.2 | 0.2 | 0.2 | 0.2 | 0.2 |
| Additives | 0.02 | 0.02 | 0.02 | 0.02 | 0.02 | 0.02 | 0.02 | 0.02 | 0.02 | 0.02 |
| Total solid content | 100 | 100 | 100 | 100 | 100 | 100 | 100 | 100 | 100 | 100 |
| (E) Solvent | 500 | 500 | 500 | 500 | 500 | 500 | 500 | 500 | 500 | 500 |
| Amount of dispersion aid | 6.47 | 6.47 | 6.47 | 6.47 | 0 | 6.47 | 2.21 | 4.21 | 6.47 | 6.47 |
| in solid content (%) | | | | | | | | | | |

The materials used in Tables 3 and 4 are as follows.

### (B) Photopolymerizable Monomer

Dipentaerythritol hexaacrylate (DPHA, Manufacturer: Nippon Kayaku Co., Ltd.)

### (C) Photopolymerization Initiator

SPI03 (Manufacturer: Samyang Corporation)

### (D) Binder Resin

SP-RY-99 (Manufacturer: Showa Denko)

### (E) Solvent

Solvent: propylene glycol monomethylether acetate (PGMEA) (Manufacturer: Daicel)

### Antioxidant

Methylhydroquinone (Manufacturer: Sigma Aldrich Co., Ltd.)

### Additive

F556 (Manufacturer: DIC Co., Ltd.)

### Evaluation Example 1: Viscosity and Particle Size of Pigment Dispersion

Each of the pigment dispersions of Preparation Examples 1 to 14 and Comparative Preparation Examples 1 to 6 was measured with respect to viscosity immediately after the dispersion at 5 rpm and 25° C. by using a Brookfield DV-II Pro viscometer and CPE-52 Spindle, and the results are shown in Table 5. In addition, the pigment dispersions were measured with respect to viscosity at ambient temperature (25° C.) after one week, and if a change rate of the viscosity to initial viscosity was less than 3%, ∘ was given, if greater than 3% and less than 5%, Δ was given, and if greater than 5%, x was given.

Each of the pigment dispersions of Preparation Examples 1 to 14 and Comparative Preparation Examples 1 to 6 was measured with respect to a particle diameter by using a dynamic light scattering analyzer (ELS-Z, Otsuka Electronics Co., Ltd.), and the results at D90 are shown in Table 5.

TABLE 5

| | | Particle | Viscosity change rate |
|---|---|---|---|
| | Viscosity | size (nm) | after 1 week at room |
| | (cP) | @D90 | temperature |
| Preparation Example 1 | 3.4 | 100 | ◯ |
| Preparation Example 2 | 3.4 | 98 | ◯ |
| Preparation Example 3 | 3.7 | 101 | ◯ |
| Preparation Example 4 | 3.8 | 99 | ◯ |
| Preparation Example 5 | 3.7 | 105 | ◯ |
| Preparation Example 6 | 3.6 | 90 | ◯ |
| Preparation Example 7 | 3.6 | 92 | ◯ |
| Preparation Example 8 | 3.9 | 101 | ◯ |
| Preparation Example 9 | 3.9 | 103 | ◯ |
| Preparation Example 10 | 4.0 | 102 | ◯ |
| Preparation Example 11 | 4.0 | 104 | ◯ |
| Preparation Example 12 | 4.0 | 105 | ◯ |
| Preparation Example 13 | 4.1 | 105 | ◯ |
| Preparation Example 14 | 4.1 | 107 | ◯ |
| Comparative Preparation | 4.8 | 95 | Δ |
| Example 1 | | | |
| Comparative Preparation | 5.5 | 101 | Δ |
| Example 2 | | | |
| Comparative Preparation | 6.4 | 116 | X |
| Example 3 | | | |
| Comparative Preparation | Gelation | N/A | N/A |
| Example 4 | | | |
| Comparative Preparation | Gelation | N/A | N/A |
| Example 5 | | | |
| Comparative Preparation | 6.1 | 115 | X |
| Example 6 | | | |

Referring to Table 5, the pigment dispersions of Preparation Examples 1 to 14, compared with the pigment dispersions of Comparative Preparation Examples 1 to 6, exhibit a small particle size and low viscosity and thus excellent dispersion stability of pigment particles, which confirms there was a small viscosity difference before and after the storage for one week.

### Evaluation Example 2: Transmittance, Chemical Resistance, and Heat Resistance of Compositions

Each of the photosensitive resin compositions was spin-coated on three glass specimens (10×10 cm) to have a thickness ranging from 0.3 μm to 0.5 μm and then prebaked at 100° C. on a hot plate for 3 minutes. Subsequently, the coated specimens were exposed to 200 mJ/cm² by using a UV light exposer and post-baked at 230° C. on the hot plate for 5 minutes. The obtained three specimens were measured with respect to a spectrum by using a colorimeter (MPCD-1, Otsuka Electronics Co., Ltd.) and with respect to a thickness by using a contact thickness-measuring device (Tencor P-16). The measured results were used to obtain transmittance corresponding to each wavelength at a thickness of 0.35 μm, which is shown in Table 6. The better coloring power of the green photosensitive resin compositions, the lower transmittance at a wavelength of 660 nm based on the same thickness.

The color specimens manufactured in the transmittance evaluation were cut to be 5 cm×5 cm and then immersed in 500 ml of PGMEA (propylene glycol methyl ether acetate) at 25° C. for 30 minutes. Color values before and after the immersion in PGMEA were measured by using a colorimeter (MCPD, Otsuka Electronics Co., Ltd). ΔEab*, which is a criterion for color changes, was calculated according to Equation 1, and the results are shown in Table 6.

The specimens manufactured in the transmittance evaluation were baked at 230° C. on the hot plate for 10 minutes. The specimens were measured with respect to color values before/after the baking by using a colorimeter, wherein ΔEab*, which is a criterion for color changes, was calculated according to Equation 1, and the results are shown in Table 6.

If ΔEab* was less than 3, ∘ was given, if greater than or equal to 3 and less than 5, Δ was given, and if greater than 5, X was given.

The pigment dispersions of Comparative Examples 4 and 5 were gelled and thus impossible to prepare as a composition.

$${{{Δ Eab *= \{ ( Δ L \text{*)}}^{2} + ( Δ a \text{*)}}^{2} + ( Δ b \text{*)}}^{2} \} \times 1 / 2 ( The smaller the Δ Eab * value , the better the heat rsistance and chemical resistance ) \qquad [ Equation 1 ]$$

TABLE 6

| | Transmittance (%) @ 0.35 μm | | | | |
|---|---|---|---|---|---|
| | @ 470 nm | | @ 660 nm | Chemical | Heat |
| | (Yellow | | (Green | resis- | resis- |
| | light | @ 520 nm | light | tance | tance |
| | absorption | (transmission | absorption | color | color |
| | region) | region) | region) | change | change |
| Example 1 | 9.5 | 89.4 | 19.5 | ◯ | ◯ |
| Example 2 | 9.5 | 89.0 | 17.2 | ◯ | ◯ |
| Example 3 | 9.4 | 89.0 | 17.2 | ◯ | ◯ |
| Example 4 | 9.4 | 88.9 | 17.5 | ◯ | ◯ |
| Example 5 | 9.5 | 90.1 | 17.3 | ◯ | ◯ |
| Example 6 | 9.4 | 89.5 | 16.7 | ◯ | ◯ |
| Example 7 | 9.4 | 89.7 | 16.8 | ◯ | ◯ |
| Example 8 | 9.6 | 88.8 | 17.8 | ◯ | ◯ |
| Example 9 | 9.6 | 88.8 | 17.8 | ◯ | ◯ |
| Example 10 | 9.6 | 88.7 | 17.9 | ◯ | ◯ |
| Example 11 | 9.6 | 88.7 | 17.8 | ◯ | ◯ |
| Example 12 | 9.6 | 88.7 | 17.9 | ◯ | ◯ |
| Example 13 | 9.7 | 88.6 | 18.3 | ◯ | ◯ |
| Example 14 | 9.7 | 88.7 | 18.3 | ◯ | ◯ |
| Comparative | 10.1 | 87.4 | 25.0 | ◯ | ◯ |
| Example 1 | | | | | |
| Comparative | 10.6 | 86.8 | 25.7 | Δ | Δ |
| Example 2 | | | | | |
| Comparative | 9.9 | 87.8 | 22.4 | ◯ | ◯ |
| Example 3 | | | | | |
| Comparative | 9.9 | 88.0 | 21.1 | ◯ | ◯ |
| Example 6 | | | | | |

Referring to Table 6, the compositions of Examples 1 to 14 exhibit lower transmittance in a wavelength region of less than or equal to 480 nm and 630 nm to 700 nm but higher transmittance in a region of 480 nm to 630 nm than the compositions of Comparative Examples 1 to 3 and 6, which confirms that sensor sensitivity of an image sensor manufactured by using the same may not only be improved, but also excellent heat resistance and chemical resistance may be achieved.

By way of summation and review, in recent years, photosensitive resin compositions for color filters using a pigment dispersion method, which may have various advantages, are required to have not only excellent pattern characteristics but also further improved performance. In particular, the characteristics of high luminance and high contrast ratio along with high color gamut are urgently required.

Meanwhile, an image sensor may be a part used for photographing images in a portable phone camera or DSC (a digital still camera). It may be classified as, e.g., a charge-coupled device (CCD) image sensor or a complementary metal oxide semiconductor (CMOS) image sensor depending upon the manufacturing process and the application method.

A color imaging device for a charge-coupled device image sensor or a complementary metal oxide semiconductor image sensor may include color filters each having filter segments of mixing primary color of red, green, and blue, and the colors may be separated.

A recent color filter mounted in the color imaging device may have a pattern size of 2 μm or less, which may be 1/100th to 1/200th of the pattern size of other color filter patterns for LCDs. Accordingly, increased resolution and decreased pattern residues may be important factors for determining the performance of a device.

Some example embodiments may provide a photosensitive resin composition that has high dispersibility and dispersion stability and may have excellent coloring power, heat resistance, and chemical resistance when implementing a color filter.

Some example embodiments may provide a photosensitive resin film manufactured using the photosensitive resin composition.

Some example embodiments may provide a color filter including the photosensitive resin film.

The photosensitive resin composition according to some example embodiments may have high dispersibility and dispersion stability, and may also have excellent coloring power, heat resistance, and chemical resistance when implementing a color filter, so that a color filter for an image sensor having excellent sensor sensitivity and a thin film such as a green color filter for an image sensor and a display device may be implemented.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photosensitive resin composition, comprising:
a colorant;
a photopolymerizable compound;
a photopolymerization initiator;
a binder resin; and
a solvent,
wherein:
the colorant includes a pigment, a dispersant, a dispersion binder, and a dispersion aid represented by Chemical Formula 1, 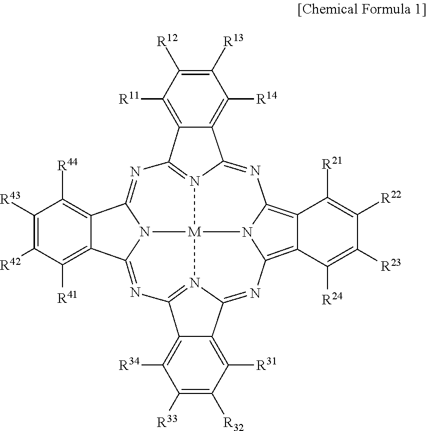
in Chemical Formula 1,
M is Cu or Zn,
R¹¹ to R¹⁴, R²¹ to R²⁴, and R³¹ to R³⁴ are each independently a hydrogen atom, a halogen atom, a hydroxy group, or a substituted or unsubstituted C1 to C20 alkyl group, and
R⁴¹ to R⁴⁴ are each independently a hydrogen atom, a halogen atom, a hydroxy group, a substituted or unsubstituted C1 to C20 alkyl group, a substituted or unsubstituted C1 to C20 alkoxy group, or a substituted or unsubstituted C6 to C20 aryloxy group, provided that at least one of R⁴¹ to R⁴⁴ is a C1 to C20 alkoxy group or a C6 to C20 aryloxy group having a substituted or unsubstituted C1 to C20 oxyalkylene group as a linking group and an amine group as a substituent at a terminal end, or a C6 to C20 aryloxy group having an amine group as a substituent at a terminal end.

2. The photosensitive resin composition as claimed in claim 1, wherein R¹¹ to R¹⁴ are all hydrogen atoms or all halogen atoms.

3. The photosensitive resin composition as claimed in claim 1, wherein one of R²¹ to R²⁴ is a substituted or unsubstituted C1 to C20 alkyl group.

4. The photosensitive resin composition as claimed in claim 1, wherein R³¹ to R³⁴ are all hydrogen atoms.

5. The photosensitive resin composition as claimed in claim 1, wherein:
one of R⁴¹ to R⁴⁴ is represented by Chemical Formula L-1 or Chemical Formula L-2: 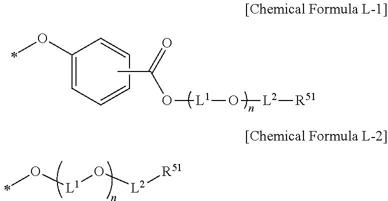
in Chemical Formula L-1 and Chemical Formula L-2,
L¹ and L² are each independently a substituted or unsubstituted C1 to C20 alkylene group,
R⁵¹ is a substituted or unsubstituted amine group, and
n is an integer of 0 to 10.

6. The photosensitive resin composition as claimed in claim 5, wherein:
R⁵¹ is represented by Chemical Formula N: 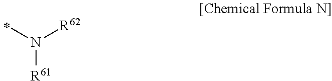
in Chemical Formula N,
R⁶¹ and R⁶² are each independently hydrogen, a substituted or unsubstituted C1 to C20 alkyl group, a substituted or unsubstituted C3 to C20 cycloalkyl group, a substituted or unsubstituted C6 to C20 aryl group, or a substituted or unsubstituted C2 to C20 heterocyclic group, and
R⁶¹ and R⁶² are each separately present or are linked to each other to form a fused ring.

7. The photosensitive resin composition as claimed in claim 5, wherein:
R⁵¹ is represented by one of Chemical Formula N-1 to Chemical Formula N-6: 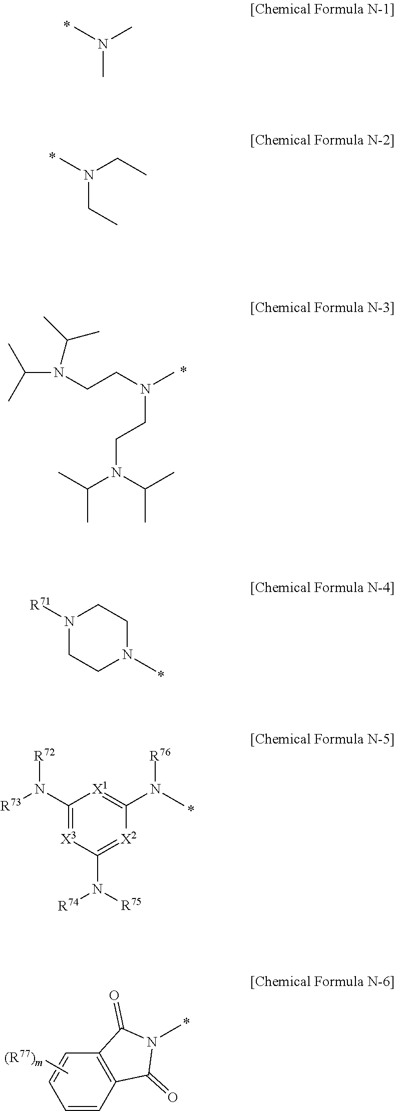
in Chemical Formula N-4 to Chemical Formula N-6,
X¹ to X³ are each independently N or CH,
R⁷¹ to R⁷⁷ are each independently hydrogen, a substituted or unsubstituted C1 to C20 alkyl group, a substituted or unsubstituted C3 to C20 cycloalkyl group, a substituted or unsubstituted C6 to C20 aryl group, or a substituted or unsubstituted C2 to C20 heterocyclic group, and
m is an integer of 0 to 4.

8. The photosensitive resin composition as claimed in claim 1, wherein the dispersion aid represented by Chemical Formula 1 is represented by one of Chemical Formulae 1-1 to 1-13:

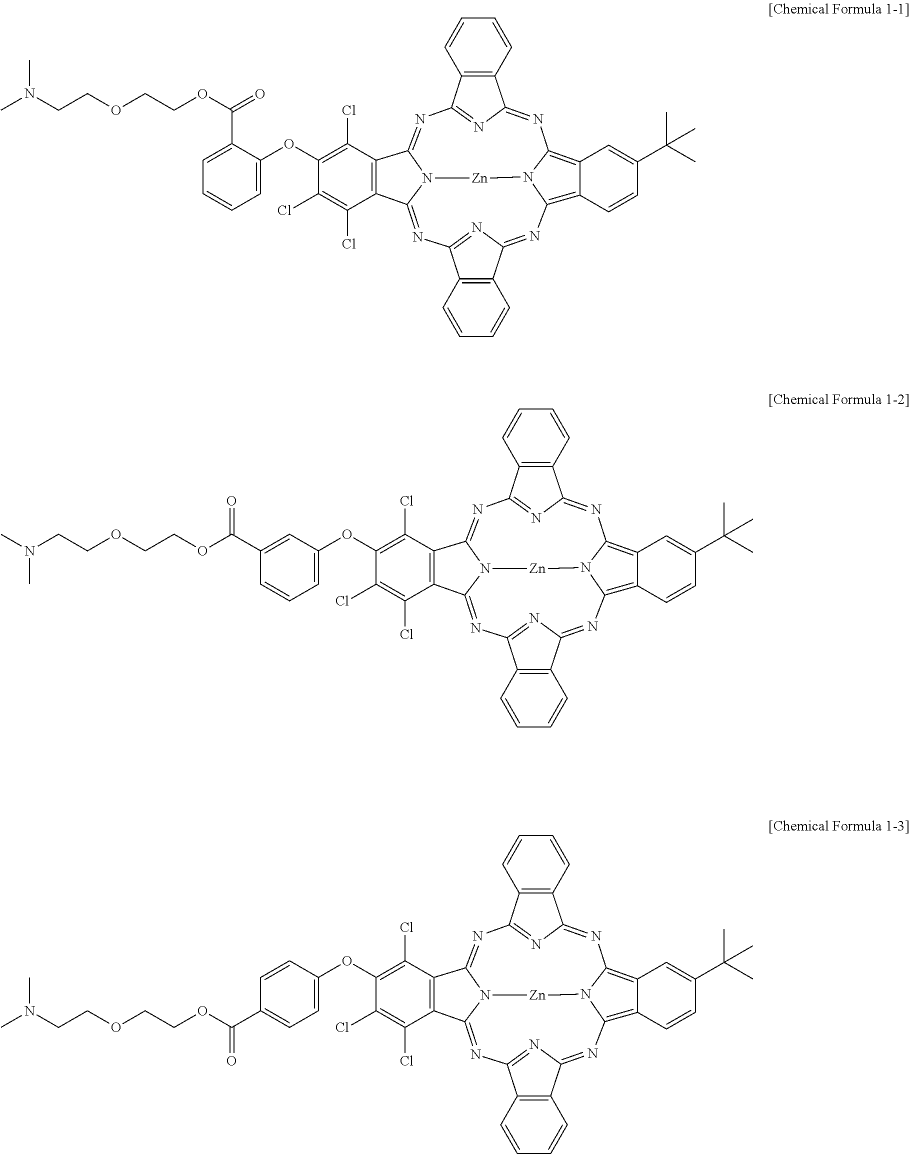

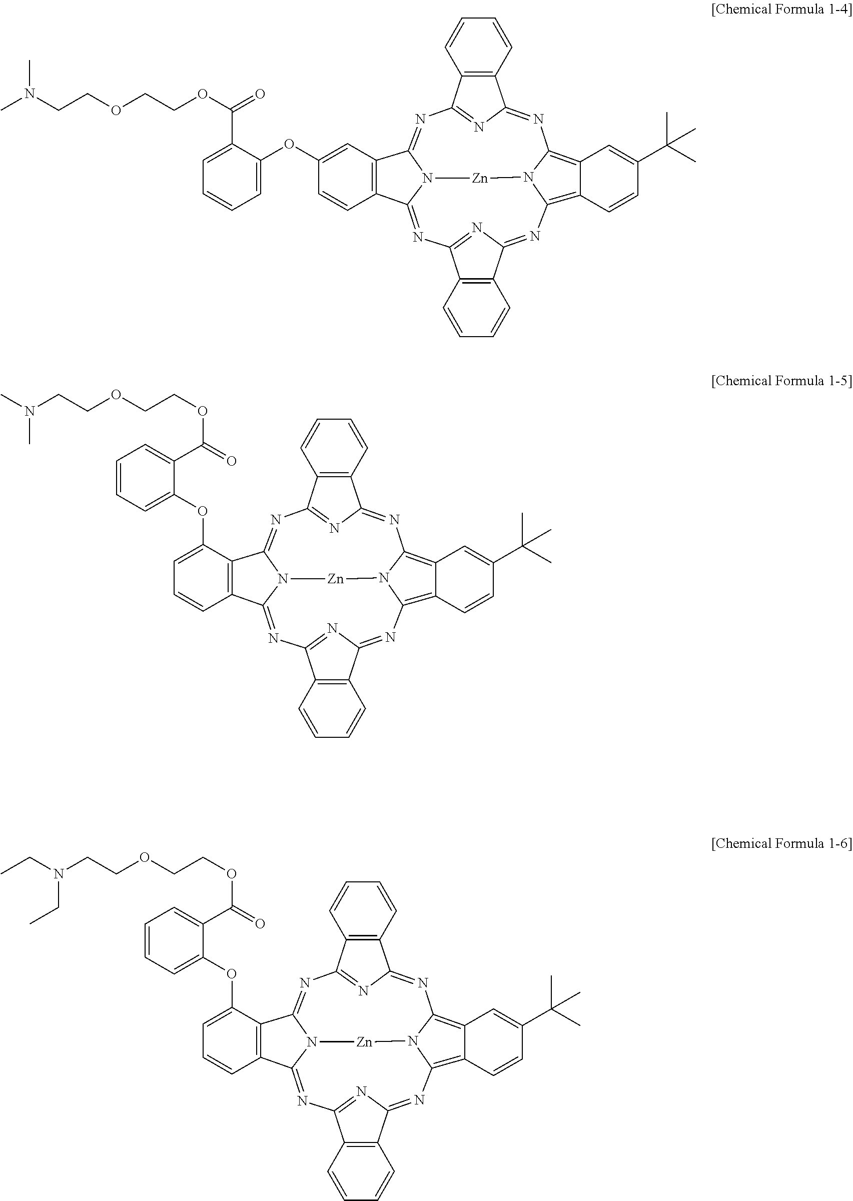

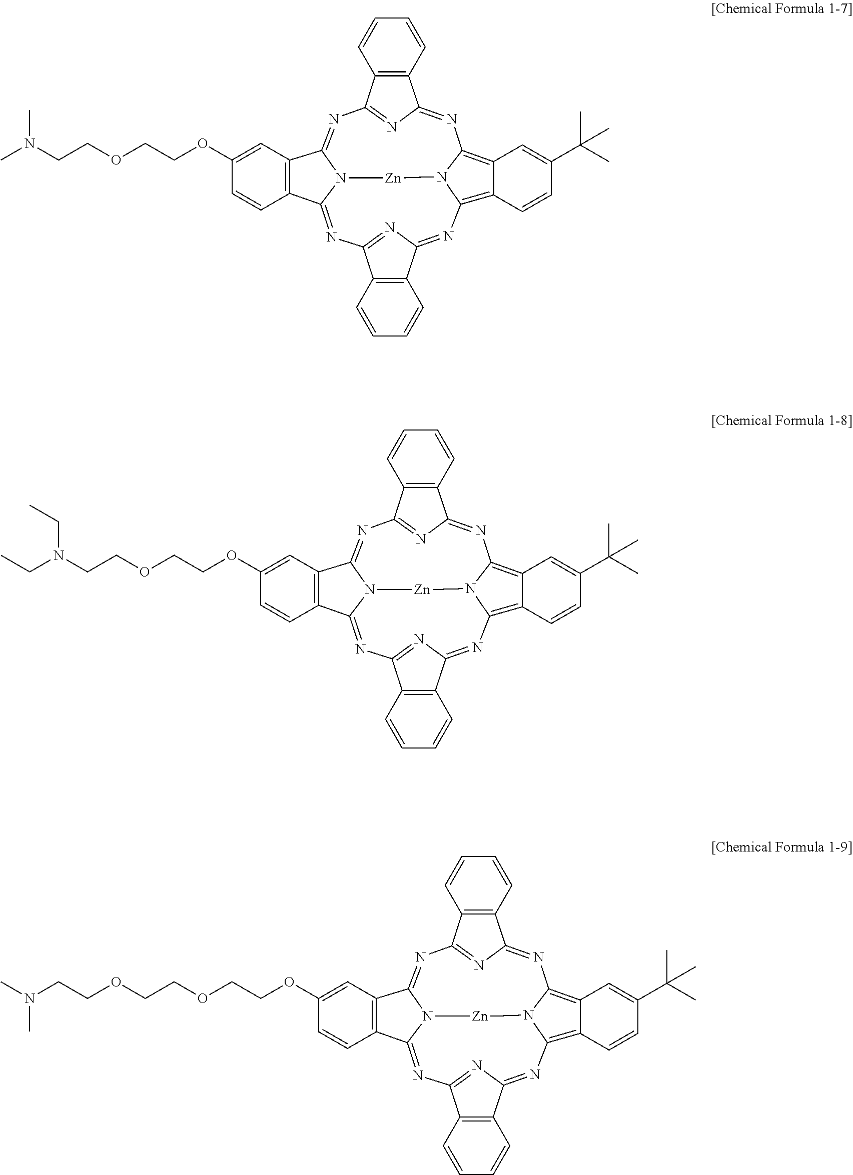

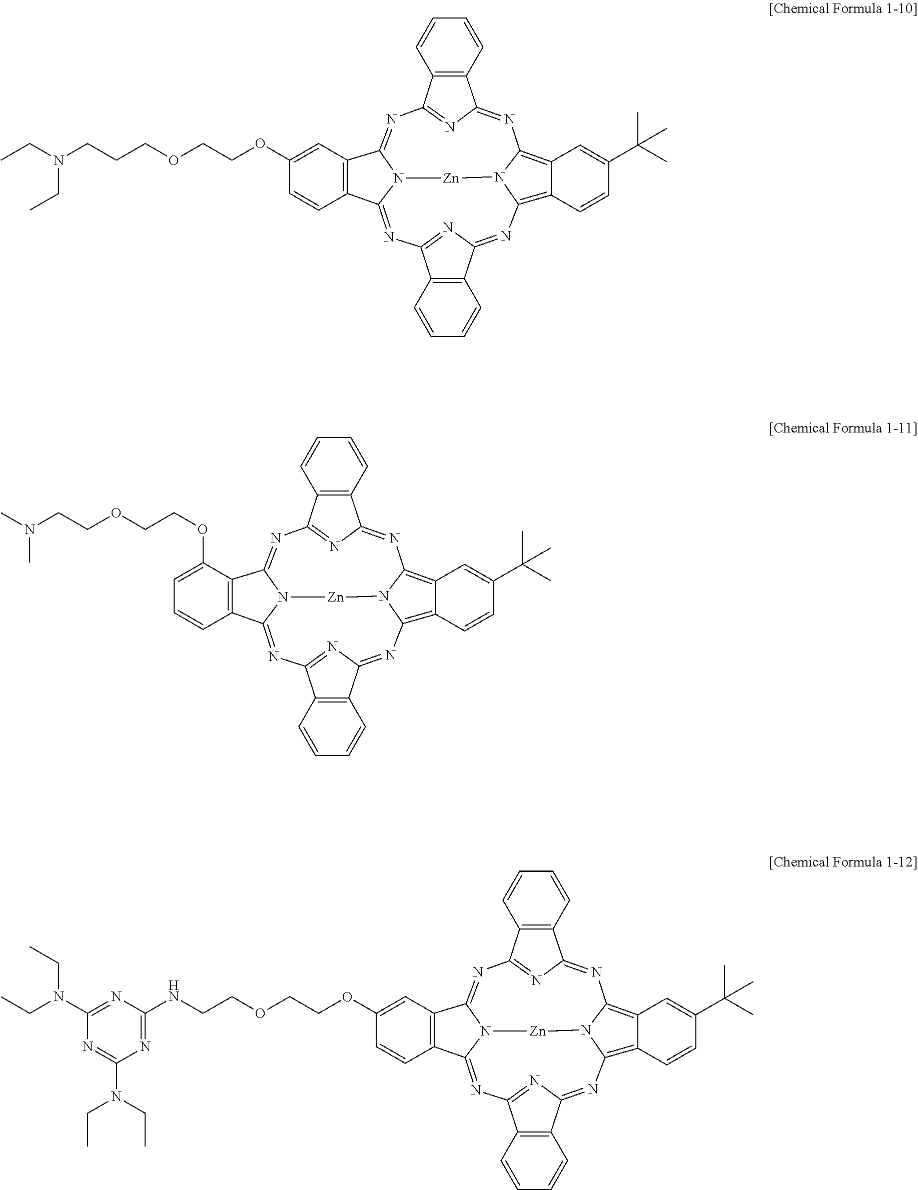

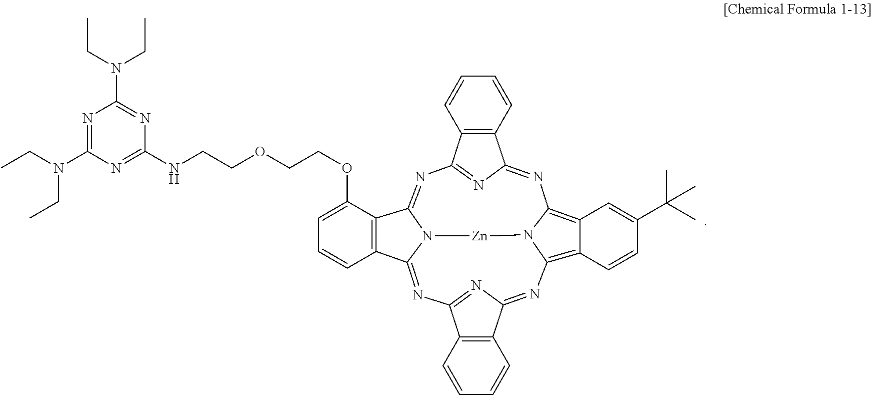

9. The photosensitive resin composition as claimed in claim 1, wherein the dispersion aid represented by Chemical Formula 1 has a maximum absorption wavelength of about 450 nm to about 495 nm.

10. The photosensitive resin composition as claimed in claim 1, wherein the dispersion aid represented by Chemical Formula 1 is included in an amount of about 3 wt % to about 8 wt %, based on a total solid content of the photosensitive resin composition.

11. The photosensitive resin composition as claimed in claim 1, wherein a weight ratio of the dispersion aid represented by Chemical Formula 1 and the pigment is about 1:3 to about 1:14.

12. The photosensitive resin composition as claimed in claim 1, wherein the pigment includes a green pigment, a yellow pigment, or a combination thereof.

13. The photosensitive resin composition as claimed in claim 1, wherein the photosensitive resin composition includes, based on a total solid content of the photosensitive resin composition:
about 30 wt % to about 70 wt % of the colorant;
about 1 wt % to about 20 wt % of the photopolymerizable compound;
about 0.1 wt % to about 5 wt % of the photopolymerization initiator;
about 0.5 wt % to about 10 wt % of the binder resin; and
the solvent.

14. The photosensitive resin composition as claimed in claim 1, wherein the photosensitive resin composition further includes an additive of malonic acid, 3-amino-1,2-propanediol, a silane coupling agent, a leveling agent, a surfactant, an antioxidant, or a combination thereof.

15. A photosensitive resin film manufactured using the photosensitive resin composition as claimed in claim 1.

16. The photosensitive resin film as claimed in claim 15, wherein the photosensitivity resin film is a negative photoresist.

17. A color filter comprising the photosensitive resin film as claimed in claim 15.
